(19) United States
(12) Patent Application Publication
(10) Pub. No.: US 2006/0232348 A1
(43) Pub. Date: Oct. 19, 2006

(54) Inductor unit and oscillator using the inductor unit

(76) Inventor: Takuo Hino, Osaka-shi (JP)

Correspondence Address: RATNERPRESTIA, P.O. BOX 980, VALLEY FORGE, PA, 19482, US

(21) Appl. No.: 11/403,048

(22) Filed: Apr. 12, 2006

(30) Foreign Application Priority Data
Apr. 19, 2005 (JP) 2005-120968

(51) Int. Cl. H03B 5/08

(52) U.S. Cl. 331/167

(57) ABSTRACT

Functionality and performance of a voltage-controlled oscillator are improved by continuously controlling inductor output by a control signal. Having a first inductor, a current detection circuit that detects current flow to the first inductor, a current source 4 for generating a current signal based on the detected current, and a second inductor to which the current signal is applied, the first inductor and second inductor are disposed to a predetermined magnetically coupled position for setting the inductance of the first inductor as desired.

### BACKGROUND OF THE INVENTION

1. Field of Technology

The present invention relates to technology for a voltage-controlled oscillator that is used in wireless communication devices having a portable terminal.

2. Description of Related Art

A voltage-controlled oscillator (VCO) is used in portable wireless devices such as cell phones for frequency conversion operations converting transmission signals to high frequency signals for transmission and converting reception signals to low frequency signals for demodulation. These applications require a wide oscillation frequency range, the ability to freely adjust the oscillation frequency, and a high carrier-to-noise (C/N) ratio in the oscillation frequency.

Semiconductor devices used in the communications industry today often have an internal voltage-controlled oscillator. Spiral inductors are generally used when the inductor is also built in to the IC device. A wide oscillation frequency band is achieved in the built-in voltage-controlled oscillator by switching between spiral inductors.

An example of this type of conventional voltage-controlled oscillator is the oscillation circuit and inductance load difference circuit shown in FIG. 36 and taught in Japanese Unexamined Patent Appl. Pub. 2004-266718.

The oscillation circuit shown in FIG. 36 is composed of a differential inductance-capacitance resonance circuit and positive feedback circuit where the resonance circuit comprises capacitor C1 and an inductance load difference circuit comprising variable inductance units Lvar1 and Lvar2, and the positive feedback circuit comprises n-channel MOS transistors M1 and M2. The variable inductance units Lvar1 and Lvar2 each have first and second input/output (I/O) terminals with the second I/O terminals connected to a common external power supply node Vdd. The first I/O terminals are connected to output nodes OUT and OUTB, respectively. The capacitor C1 is also connected to the first I/O terminals of the variable inductance units Lvar1 and Lvar2. The oscillation frequency of the voltage-controlled oscillator can be determined from the inductance of the variable inductance unit and the capacitance.

The variable inductance units Lvar1 and Lvar2 vary the inductance and control the oscillation frequency by switching a plurality of switch circuits SW1, SW2, SW3, SW1d, SW2d, and SW3d disposed between a plurality of selected positions on the spiral wiring layer and the I/O terminals. The variable inductance units Lvar1 and Lvar2 form an inductor pair when switch SWndd of switch circuits SW1, SW2, SW3 connected between the first I/O terminals is ON at the same time as switch circuits SWn and SWnd.

See Japanese Unexamined Patent Appl. Pub. 2002-151953 and Japanese Unexamined Patent Appl. Pub. 2004-266718.

The variable inductance units taught in the patents cited above are composed of serial-parallel circuits comprising a plurality of inductors and a plurality of switch circuits, and changes the overall inductance in steps by turning the switch circuits on or off. As a result, the oscillation frequency of the voltage-controlled oscillator also changes in steps.

This arrangement increases the bandwidth of the voltage-controlled oscillator but does not afford sufficiently fine tuning the oscillation frequency because correcting for variation in the inductors built in to the IC device is deficient.

The oscillation frequency band can also not be freely set, and correcting for the capacitance-voltage nonlinearity and temperature characteristic of a varactor diode is not possible.

The present invention is directed to solving these problems, and an object of the invention is to improve the functionality and performance of a voltage-controlled oscillator by enabling continuously controlling the inductor by a control signal.

### SUMMARY OF THE INVENTION

To achieve this object, an inductor unit according to the present invention comprises a first inductor; a current signal generator operable to detect an electric signal denoting current flowing to the first inductor or the voltage at both ends of the first inductor, and to generate a current signal based on the electric signal; and a second inductor that receives the current signal. The first inductor and second inductor are disposed to a predetermined magnetically coupled position and the inductance of the first inductor is set desirably.

An oscillator having this inductor unit comprises the inductor unit and a variable capacitance device connected to the inductor unit. The oscillator oscillates at an oscillation frequency determined by the inductance of the inductor unit and the capacitance of the variable capacitance device.

An inductor unit according to the present invention and an oscillator using the inductor unit can continuously control the inductance of the inductor unit by a control signal, and can continuously control the oscillation frequency of a voltage-controlled oscillator that uses this inductor. An inductor that conventionally cannot be controlled using a passive element can thus be rendered as an active device that can be controlled continuously.

An inductor with such a continuously variable output function also enables precisely compensating for variations in inductor output resulting from the semiconductor manufacturing process, and enables accurately tuning the oscillation frequency of the voltage-controlled oscillator.

Furthermore, by continuously varying the oscillation frequency of the voltage-controlled oscillator, the voltage-controlled oscillator can be freely switched to operate at one of a plurality of frequency bands.

Furthermore, by the nonlinearity of the variable capacitance device and the temperature characteristic of the variable capacitance device and fixed capacitors can be corrected to the ideal characteristic. Because the conversion gain Kv of the voltage-controlled oscillator is constant regardless of capacitance control signal, the lockup time and C/N characteristic of the PLL incorporating the voltage-controlled oscillator are constant to the oscillation frequency, and a stable oscillation characteristic can be achieved.

The inductor unit of the present invention can directly increase the inductance and therefore increase the Q of the inductor by a serial resistance, and can therefore also improve the C/N ratio of the oscillation frequency of the voltage-controlled oscillator.

By also using the variable capacitance function of the variable capacitance device, the resonance frequency can be controlled without great variation in the inductance-capacitance ratio. A wider oscillation frequency band can thus be achieved, and a stable oscillation characteristic can be achieved across a wide frequency range.

Other objects and attainments together with a fuller understanding of the invention will become apparent and appreciated by referring to the following description and claims taken in conjunction with the accompanying drawings.

### BRIEF DESCRIPTION OF THE DRAWINGS

FIG. 1 is a block diagram of an inductor unit according to a first embodiment of the invention.

FIG. 2 is a block diagram of the inductor unit according to a first variation of the first embodiment of the invention.

FIG. 3 is a block diagram of the inductor unit according to a second variation of the first embodiment of the invention.

FIG. 4 is a block diagram of the inductor unit according to a third variation of the first embodiment of the invention.

FIG. 5A is a partial circuit diagram of the inductor unit in the first embodiment and the first variation of the first embodiment.

FIG. 5B is a partial circuit diagram of the inductor unit in the first embodiment and the first variation of the first embodiment.

FIG. 5C is a partial circuit diagram of the inductor unit in the first embodiment and the first variation of the first embodiment.

FIG. 5D is a partial circuit diagram of the inductor unit in the first embodiment and the first variation of the first embodiment.

FIG. 5E is a partial circuit diagram of the inductor unit in the first embodiment and the first variation of the first embodiment.

FIG. 6A is a partial circuit diagram of the inductor unit in second and third variations of the first embodiment.

FIG. 6B is a partial circuit diagram of the inductor unit in second and third variations of the first embodiment.

FIG. 6C is a partial circuit diagram of the inductor unit in second and third variations of the first embodiment.

FIG. 6D is a partial circuit diagram of the inductor unit in second and third variations of the first embodiment.

FIG. 6E is a partial circuit diagram of the inductor unit in second and third variations of the first embodiment.

FIG. 7 is a plan view of a semiconductor device comprising an inductor according to the first embodiment of the invention.

FIG. 8 is an oblique view of a semiconductor device comprising an inductor according to the first embodiment of the invention.

FIG. 9 is a block diagram of a voltage-controlled oscillator according to a second embodiment of the invention.

FIG. 10 is a circuit diagram of the voltage-controlled oscillator according to the second embodiment of the invention.

FIG. 11 is a block diagram of a voltage-controlled oscillator according to a first variation of the second embodiment of the invention.

FIG. 12 is a circuit diagram of a voltage-controlled oscillator according to a first variation of the second embodiment of the invention.

FIG. 13 is a block diagram of a voltage-controlled oscillator according to a second variation of the second embodiment of the invention.

FIG. 14 is a circuit diagram of a voltage-controlled oscillator according to a second variation of the second embodiment of the invention.

FIG. 15 is a block diagram of a voltage-controlled oscillator according to a third variation of the second embodiment of the invention.

FIG. 16 is a circuit diagram of a voltage-controlled oscillator according to a third variation of the second embodiment of the invention.

FIG. 17 is a block diagram of a voltage-controlled oscillator according to a fourth variation of the second embodiment of the invention.

FIG. 18 is a block diagram of a voltage-controlled oscillator according to a fifth variation of the second embodiment of the invention.

FIG. 19 is a block diagram of a voltage-controlled oscillator according to a sixth variation of the second embodiment of the invention.

FIG. 20 is a block diagram of a voltage-controlled oscillator according to a seventh variation of the second embodiment of the invention.

FIG. 21 is a block diagram of a voltage-controlled oscillator according to an eighth variation of the second embodiment of the invention.

FIG. 22 is a block diagram of a voltage-controlled oscillator according to a ninth variation of the second embodiment of the invention.

FIG. 23 is a block diagram of a voltage-controlled oscillator according to a tenth variation of the second embodiment of the invention.

FIG. 24 is a block diagram of a voltage-controlled oscillator according to an eleventh variation of the second embodiment of the invention.

FIG. 25 is a block diagram of a voltage-controlled oscillator according to a twelfth variation of the second embodiment of the invention.

FIG. 26 is a block diagram of a voltage-controlled oscillator according to a thirteenth variation of the second embodiment of the invention.

FIG. 27 is a block diagram of a voltage-controlled oscillator according to a fourteenth variation of the second embodiment of the invention.

FIG. 28 is a block diagram of a voltage-controlled oscillator according to a fifteenth variation of the second embodiment of the invention.

FIG. 29 shows the relationship between the capacitance of the varactor diode and the capacitance control signal.

FIG. 30 shows the relationship between the oscillation frequency of the voltage-controlled oscillator and the capacitance control signal.

FIG. 31 shows the relationship between the capacitance control signal and the oscillation frequency using the frequency band signal is a parameter.

FIG. 32 shows the relationship between the oscillation frequency and capacitance control signal using temperature as a parameter.

FIG. 33 is a circuit diagram of the voltage-current conversion circuit in a ninth variation of the second embodiment of the invention.

FIG. 34 is a circuit diagram of the voltage-current conversion circuit in an eleventh variation of the second embodiment of the invention.

FIG. 35 is a block diagram of an inductor unit comprising a 90-degree phase inversion shift circuit.

FIG. 36 is a block diagram of a voltage-controlled oscillator according to the prior art.

### DETAILED DESCRIPTION OF THE PREFERRED EMBODIMENTS

Preferred embodiments of the present invention are described below with reference to the accompanying figures. The first embodiment below describes an inductor unit according to the present invention, and the second embodiment below describes a voltage-controlled oscillator according to the present invention.

Numeric values shown in the following embodiments are used by way of example only to describe the invention, and the invention is not limited to using these values.

### First Embodiment

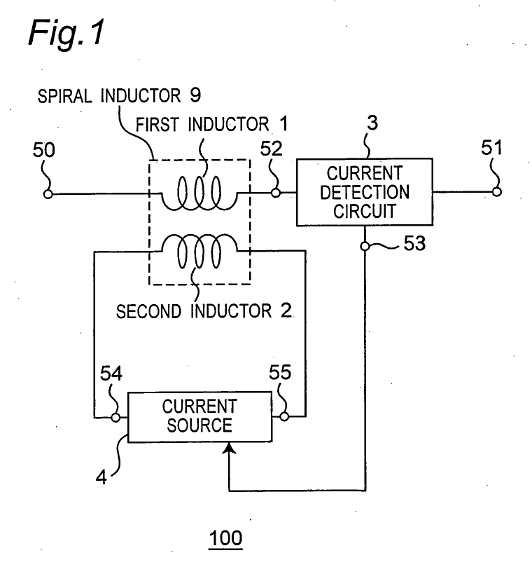

FIG. 1 is a block diagram of an inductor unit according to a first embodiment of the invention.

One end of the first inductor 1 is connected to a current detection circuit 3 through node 52, and the other end of the first inductor 1 is connected to node 50. The current detection circuit 3 is connected to node 51 and node 53 in addition to node 52. The current source 4 is connected to the current detection circuit 3 through node 53, and is connected through node 54 and node 55 to one side and the other side, respectively, of the second inductor 2. The circuitry between node 50 and node 51 is inductor unit 100.

The current flowing to the first inductor 1 also flows between node 51 and node 52 through the current detection circuit 3, and the frequency, phase, and current amplitude of the current are detected by the current detection circuit 3. The current source 4 generates a current signal of the same frequency, same phase, and current amplitude of a predetermined current-amplitude ratio K1 to the current detected by the current detection circuit 3. The resulting current signal flows through node 54 and node 55 to the second inductor 2. The value of the current-amplitude ratio K1 is positive, negative, or zero, and is constant relative to the current amplitude of the input current.

The first inductor 1 and second inductor 2 constituting the spiral inductor 9 are disposed to a position that is magnetically coupled by mutual induction. Depending on the sign of the current-amplitude ratio K1, the magnetic flux produced by the second inductor 2 works to increase or decrease the magnetic flux produced by the first inductor 1. In this embodiment of the invention the magnetic flux from the second inductor 2 works to increase the magnetic flux from the first inductor 1 when current-amplitude ratio K1 is positive, and to decrease the magnetic flux of first inductor 1 when the current-amplitude ratio K1 is negative.

The apparent inductance of the first inductor 1 reflecting the mutual induction of the magnetic flux from the second inductor 2 on the magnetic flux from the first inductor 1 is the inductance of the inductor unit 100, and if the current-amplitude ratio K1 of the current source 4 or the amplitude of the current signal flowing through the second inductor 2 changes continuously, the inductance of the inductor unit 100 also changes continuously and can be set to a desired level.

Furthermore, when current-amplitude ratio K1 is positive, the inductance of the inductor unit 100 increases and the resistance of the first inductor 1 does not change. As a result, the Q of the inductance of the inductor unit 100 increases compared with the first inductor 1 alone.

The current flowing through the first inductor 1 in this embodiment of the invention is just one example of an electric signal denoting an electrical state variable of the first inductor 1.

Note, further, that the current detection circuit 3 and current source 4 constitute a current signal generator.

First Variation of the First Embodiment

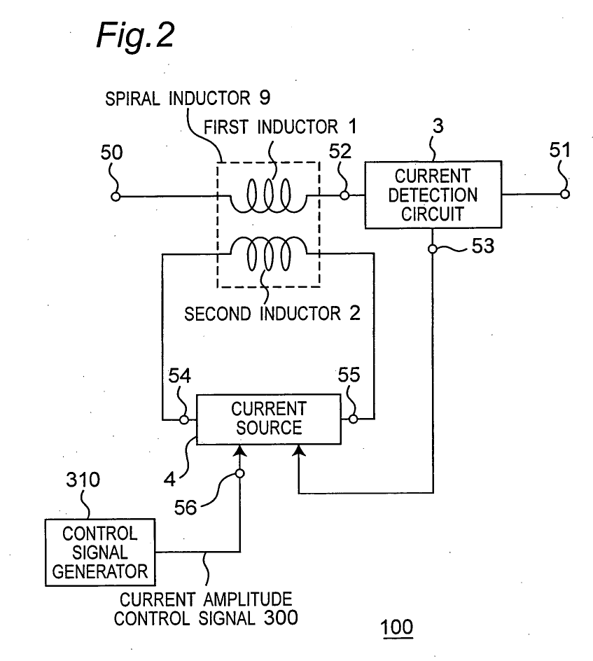

FIG. 2 is a block diagram of the inductor unit 100 according to a first variation of the first embodiment of the invention.

This variation differs from the inductor unit 100 shown in FIG. 1 in that a current amplitude control signal 300 input from node 56 continuously varies the amplitude of the current signal flowing through the second inductor 2. As a result, the amplitude of the current signal or the current-amplitude ratio K1 of the current signal flowing through the second inductor 2 can be continuously controlled based on the current amplitude control signal 300. In addition, the inductance of the inductor unit 100 can be continuously varied and set as desired by the current amplitude control signal 300.

This current amplitude control signal 300 is generated by the control signal generator 310.

Second Variation of the First Embodiment

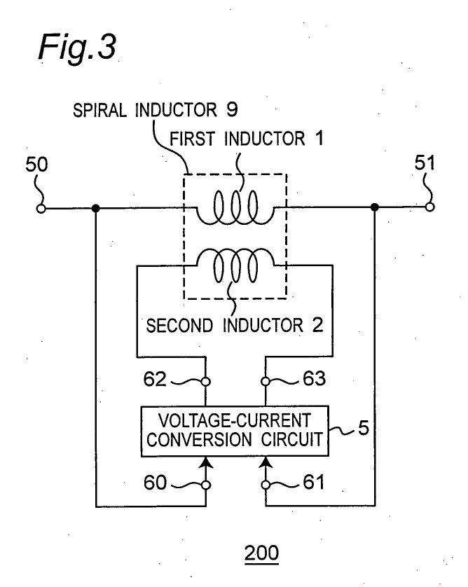

FIG. 3 is a block diagram of an inductor unit according to a second variation of the first embodiment of the invention.

One side of the first inductor 1 is connected to node 50 and is connected to the voltage-current conversion circuit 5 through node 60. The other side of the first inductor 1 is connected to node 51 and is connected to the voltage-current conversion circuit 5 through node 61. The voltage-current conversion circuit 5 is connected to both sides of the second inductor 2 through node 62 and node 63. The circuitry between node 50 and node 51 is inductor unit 200.

The voltage at both ends of the first inductor 1 is input to the voltage-current conversion circuit 5. The voltage-current conversion circuit 5 generates a current signal having a current amplitude of a predetermined voltage-current conversion ratio K2 and the same frequency as the input voltage, and this current signal flows through node 62 and node 63 to the second inductor 2. The value of the voltage-current conversion ratio K2 is positive, negative, or zero, and is constant relative to the voltage amplitude of the input voltage.

The first inductor 1 and second inductor 2 constituting the spiral inductor 9 are disposed to a position that is magnetically coupled by mutual induction. Depending on the sign of the voltage-current conversion ratio K2, the magnetic flux produced by the second inductor 2 works to increase or decrease the magnetic flux produced by the first inductor 1. In this embodiment of the invention the magnetic flux from the second inductor 2 works to increase the magnetic flux from the first inductor 1 when voltage-current conversion ratio K2 is positive, and to decrease the magnetic flux of first inductor 1 when the voltage-current conversion ratio K2 is negative.

The apparent inductance of the first inductor 1 reflecting the mutual induction of the magnetic flux from the second inductor 2 on the magnetic flux from the first inductor 1 is the inductance of the inductor unit 200, and if the voltage-current conversion ratio K2 of the voltage-current conversion circuit 5 or the amplitude of the current signal flowing through the second inductor 2 changes continuously, the inductance of the inductor unit 200 also changes continuously and can be set to a desired level.

Furthermore, when voltage-current conversion ratio K2 is positive, the inductance of the inductor unit 200 increases and the resistance of the first inductor 1 does not change. As a result, the Q of the inductance of the inductor unit 200 increases compared with the first inductor 1 alone.

The voltage at both ends of the first inductor 1 in this embodiment of the invention is just one example of an electric signal denoting an electrical state variable of the first inductor 1.

Note, further, that the voltage-current conversion circuit 5 constitutes a current signal generator.

Third Variation of the First Embodiment

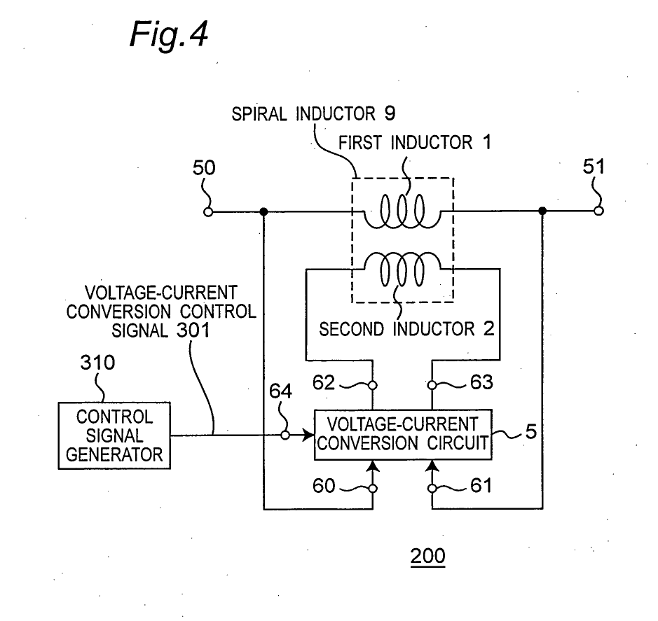

FIG. 4 is a block diagram of the inductor unit 200 according to a third variation of the first embodiment of the invention.

This variation differs from the inductor unit 200 shown in FIG. 3 in that a voltage-current conversion control signal 301 input from node 64 continuously varies the amplitude of the current signal flowing through the second inductor 2. As a result, the amplitude of the current signal or the voltage-current conversion ratio K2 of the current signal flowing through the second inductor 2 can be continuously controlled based on the voltage-current conversion control signal 301. In addition, the inductance of the inductor unit 200 can be continuously varied and set as desired by the voltage-current conversion control signal 301.

The voltage-current conversion control signal 301 is generated by the control signal generator 310.

Partial Circuit Diagram for the First Embodiment and First Variation of the First Embodiment

Block diagrams of the major circuit block of the first embodiment and the first, second, and third variations of the first embodiment are described next.

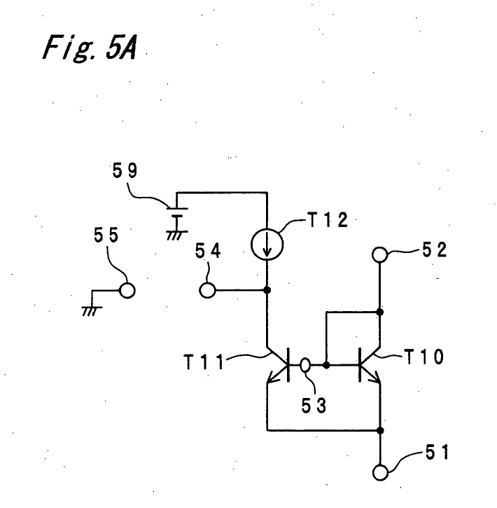

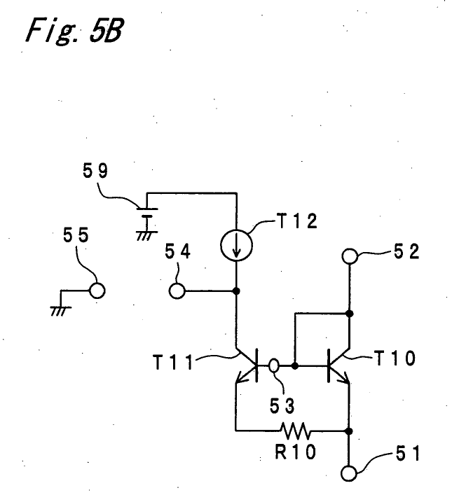

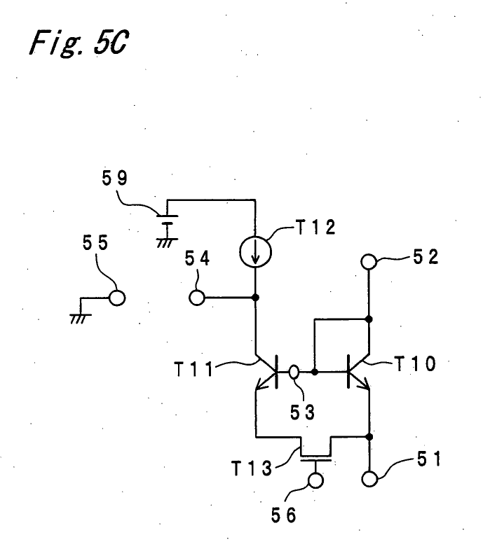

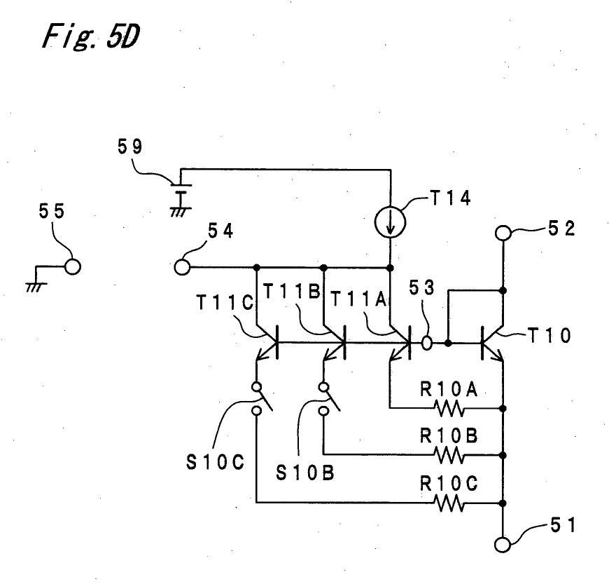

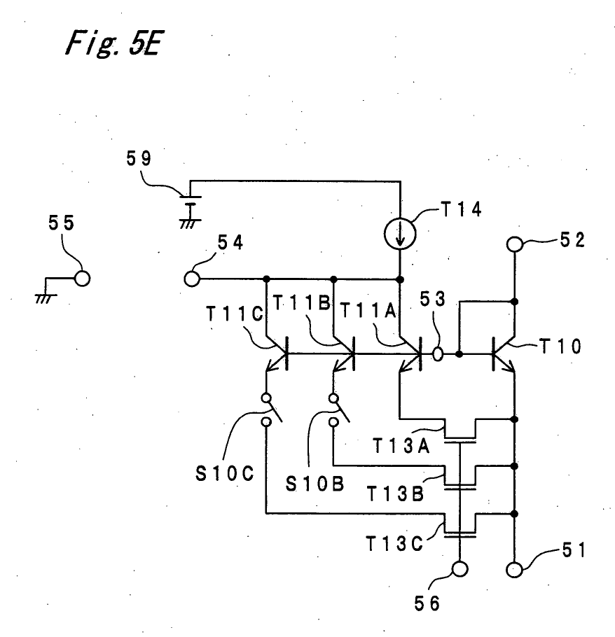

FIG. 5 is a partial circuit diagram of the inductor unit 100 in the first embodiment and first variation of the first embodiment described above.

Referring to FIG. 5A, node 52 in FIG. 1 is connected to the collector and base of transistor T10, the base of transistor T10 is connected to node 53 and the base of transistor T11, and the emitter of transistor T10 is connected to the emitter of transistor T11 and node 51 shown in FIG. 1. The collector of transistor T11 is connected to node 54 and through transistor T12 to current source 59. The second inductor 2 is connected between node 54 and the ground node 55 as shown in FIG. 1.

With the arrangement shown in FIG. 5A, the current flowing through the first inductor 1 flows between the collector and emitter of transistor T10, and a current signal substantially proportional to the size ratio of transistor T11 to T10 flows between transistor T10 and the collector and emitter of the transistor T11 forming a current mirror circuit. This current signal also flows to the second inductor 2 connected to node 54 and node 55. The operation of the inductor unit 100 in the first embodiment of the invention is thus described using the specific circuit design shown in FIG. 5A.

In FIG. 5B, a resistance R10 is inserted between the emitter of transistor T11 and node 51. If VBE is the voltage between the base and emitter of transistor T11, a current signal proportional to VBE/R10 flows to the second inductor 2. If resistance R10 changes, the current signal flowing to the second inductor 2 changes.

In FIG. 5C, a MOS transistor T13 is inserted between the emitter of transistor T11 and node 51, and the gate of MOS transistor T13 is connected to node 56. As described in FIG. 2, the gate voltage of MOS transistor T13 changes and the ON resistance between the drain and source of MOS transistor T13 changes continuously according to the current amplitude control signal 300 from node 56. As a result, the current signal flowing to the second inductor 2 between node 54 and node 55 also changes continuously. With the arrangement shown in FIG. 5C, the current-amplitude ratio K1 of the current signal or the amplitude of the current signal flowing through the second inductor 2 can therefore be controlled continuously based on the current amplitude control signal 300.

Three parallel sets of transistor T11 and resistance R10 as shown in FIG. 5B, specifically transistor T11A and resistance R10A, transistor T11B and resistance R10B, and transistor T11C and resistance R10C, are rendered in the arrangement shown in FIG. 5D. Switch S10B and switch S10C, respectively, are connected between transistor T11B and resistance R10B, and transistor T11C and resistance R10C. The current capacity of constant-current source T14 is greater than that of constant-current source T12. With this arrangement, the current signal flowing to the second inductor 2 is changed in steps by switch S10B and switch S10C.

The arrangement shown in FIG. 5E replaces the three resistances R10A, R10B, R10C shown in FIG. 5D with three MOS transistors T13A, T13B, T13C. The current signal flowing to the second inductor 2 is changed in steps by switch S10B and switch S10C, and the current amplitude control signal 300 from node 56 changes the current signal continuously within each step. Based on current amplitude control signal 300, the arrangement shown in FIG. 5E can therefore control the current-amplitude ratio K1 of the current signal or the amplitude of the current signal flowing to the second inductor 2 both in steps and continuously within each step.

Partial Circuit Diagram for the Second and Third Variations of the First Embodiment

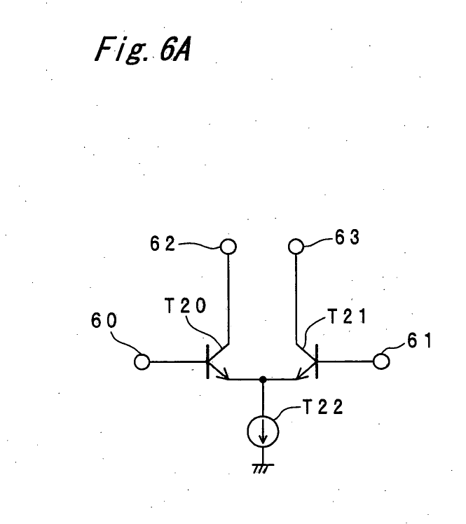

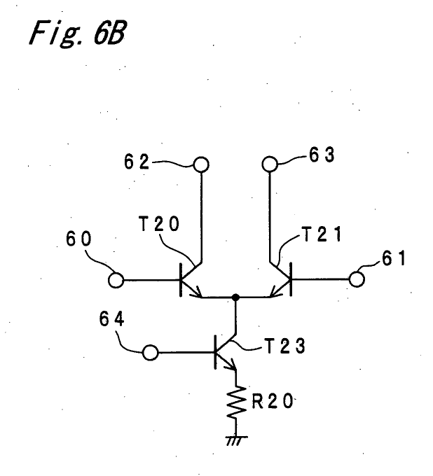

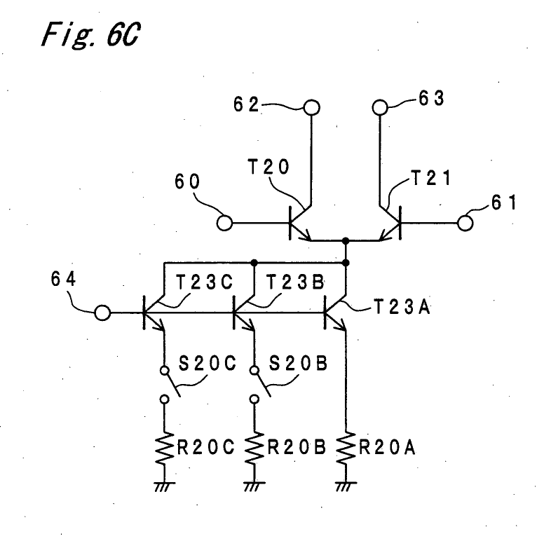

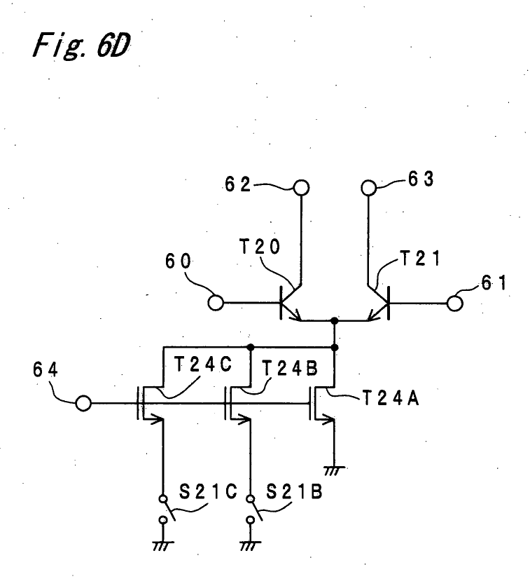

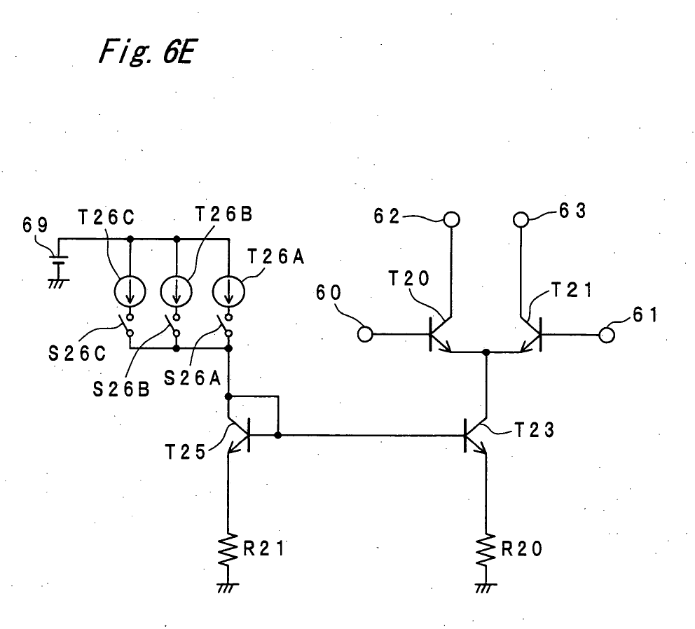

FIG. 6 is a partial circuit diagram of the inductor unit 200 in the second and third variations of the first embodiment described above.

In FIG. 6A transistor T20 and transistor T21 are in a differential arrangement with the emitter of each going to ground through constant-current source T22. The bases of transistor T20 and T21 are connected to node 60 and node 61, respectively, and the collectors are connected to node 62 and node 63, respectively.

With the arrangement shown in FIG. 6A, voltage is input from node 60 and node 61 to both ends of the first inductor 1, and a current signal proportional to the voltage produced by the differential amplifier composed of transistor T20 and transistor T21 is supplied through node 62 and node 63 to the second inductor 2.

The arrangement shown in FIG. 6B replaces the constant-current source T22 shown in FIG. 6A with transistor T23 and resistance R20. The base of transistor T23 is connected to node 64. The base voltage of transistor T23 varies and the collector current of transistor T23 varies continuously with the voltage-current conversion control signal 301 from node 64 shown in FIG. 4, and the current signal flowing through the second inductor 2 between node 62 and node 63 thus also varies continuously. With the arrangement shown in FIG. 6B, therefore, the voltage-current conversion ratio K2 of the current signal or the amplitude of the current signal flowing through the second inductor 2 can be controlled continuously by the voltage-current conversion control signal 301.

Three parallel sets of transistor T23 and resistance R20 as shown in FIG. 6B, specifically transistor T23A and resistance R20A, transistor T23B and resistance R20B, and transistor T23C and resistance R20C, are rendered in the arrangement shown in FIG. 6C. Switch S20B and switch S20C, respectively, are connected between transistor T23B and resistance R20B, and transistor T23C and resistance R20C. With this arrangement, the current signal flowing to the second inductor 2 is changed in steps by switch S20B and switch S20C, and varied continuously within each step by the voltage-current conversion control signal 301 from node 64.

Based on voltage-current conversion control signal 301, the arrangement shown in FIG. 6C can therefore control the voltage-current conversion ratio K2 of the current signal or the amplitude of the current signal flowing to the second inductor 2 both in steps and continuously within each step.

The arrangement shown in FIG. 6D replaces the three transistor-resistor sets, specifically transistor T23A and resistance R20A, transistor T23B and resistance R20B, and transistor T23C and resistance R20C, with MOS transistors T24A, T24B, and T24C, respectively. Similarly to the arrangement shown in FIG. 6C, this arrangement changes the current signal flowing to the second inductor 2 in steps by switches S20B and S20C, and continuously within each step by the voltage-current conversion control signal 301 applied from node 64.

Based on voltage-current conversion control signal 301, the arrangement shown in FIG. 6D can therefore control the voltage-current conversion ratio K2 of the current signal or the amplitude of the current signal flowing to the second inductor 2 both in steps and continuously within each step.

The arrangement shown in FIG. 6E disposes transistor T25 and resistance R21 rendering a current mirror circuit to transistor T23 and resistance R20 shown in FIG. 6B. The collector of transistor T25 is connected to one side of switches S26A, S26B, S26C. The other side of each switch S26A, S26B, S26C is connected to DC power supply 69 through constant-current source T26A, T26B, T26C, respectively.

With the arrangement shown in FIG. 6E, the current output from each constant-current source T26A, T26B, T26C is weighted differently. The current flow to transistor T25 and transistor T23 can be varied in steps by setting switches S26A, S26B, S26C as needed. The arrangement shown in FIG. 6E can thus control the amplitude of the current signal or the voltage-current conversion ratio K2 of the current signal flowing through the second inductor 2 in steps.

Plan View and Oblique View of the First Embodiment

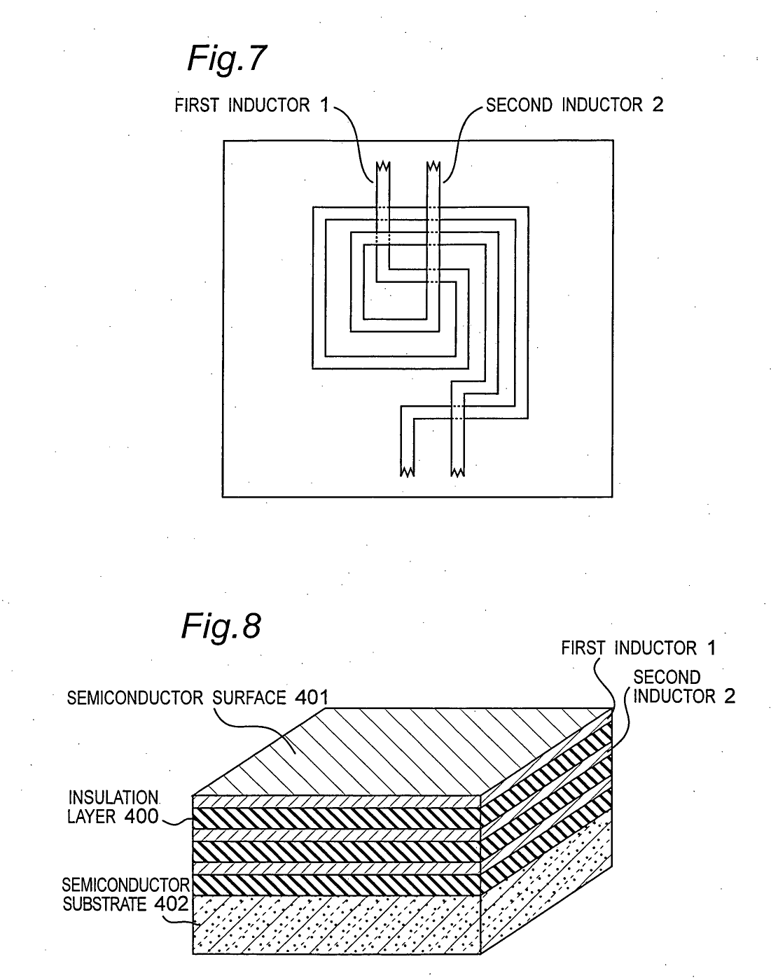

FIG. 7 is a plan view of a semiconductor device comprising an inductor according to the first embodiment of the invention. The first inductor 1 and second inductor 2 shown in FIG. 7 are strip conductors wound in a spiral with one or more turns, are respectively formed on a first layer and a second layer of the semiconductor device, and together form the spiral inductor 9 described in the first embodiment of the invention. The first inductor 1 and second inductor 2 are generally formed in an aluminum wiring process during semiconductor device manufacture.

FIG. 8 is an oblique view of a semiconductor device comprising an inductor according to the first embodiment of the invention.

An insulation layer 400 intervenes between the first inductor 1 and second inductor 2, thereby electrically isolating the first inductor 1 and second inductor 2.

The first inductor 1 is rendered on the semiconductor surface 401 and the second inductor 2 is rendered on the semiconductor substrate 402 side of the semiconductor device with the insulation layer 400 therebetween in a stacked arrangement. This arrangement reduces the chip area needed to render the first inductor 1 and second inductor 2, and enables easier magnetic coupling by mutual induction. Parasitic capacitance between the first inductor 1 and semiconductor substrate 402 can also be reduced and the Q of the first inductor 1 increased as a result of disposing the first inductor 1 on the semiconductor surface 401 at a position separated from the semiconductor substrate 402, and electromagnetically shielding the first inductor 1 from the semiconductor substrate 402 by the second inductor 2 therebetween.

The first inductor 1 and second inductor 2 are rendered on a first layer and second layer, respectively, in this arrangement, but two spiraled strip conductors could be rendered in the same layer.

The first layer and second layer are also rendered on a semiconductor substrate 402 in this embodiment, but could be rendered on a dielectric substrate or an insulating substrate such as a glass substrate or a plastic substrate.

As described above, the inductor unit of this first embodiment of the invention enables continuously varying and desirably setting the inductance of the inductor by current amplitude control signal 300 or voltage-current conversion control signal 301. As a result, an inductor that conventionally cannot be controlled by a passive element can be rendered as an active device that can be controlled continuously. An inductor with such a continuously variable output function also enables precisely compensating for variations in inductor output resulting from the semiconductor manufacturing process.

The inductor unit of this invention enables increasing only the inductance without changing the serial resistance, and thus enables increasing the Q of the inductor.

### Second Embodiment

The second embodiment of the invention described below is a voltage-controlled oscillator.

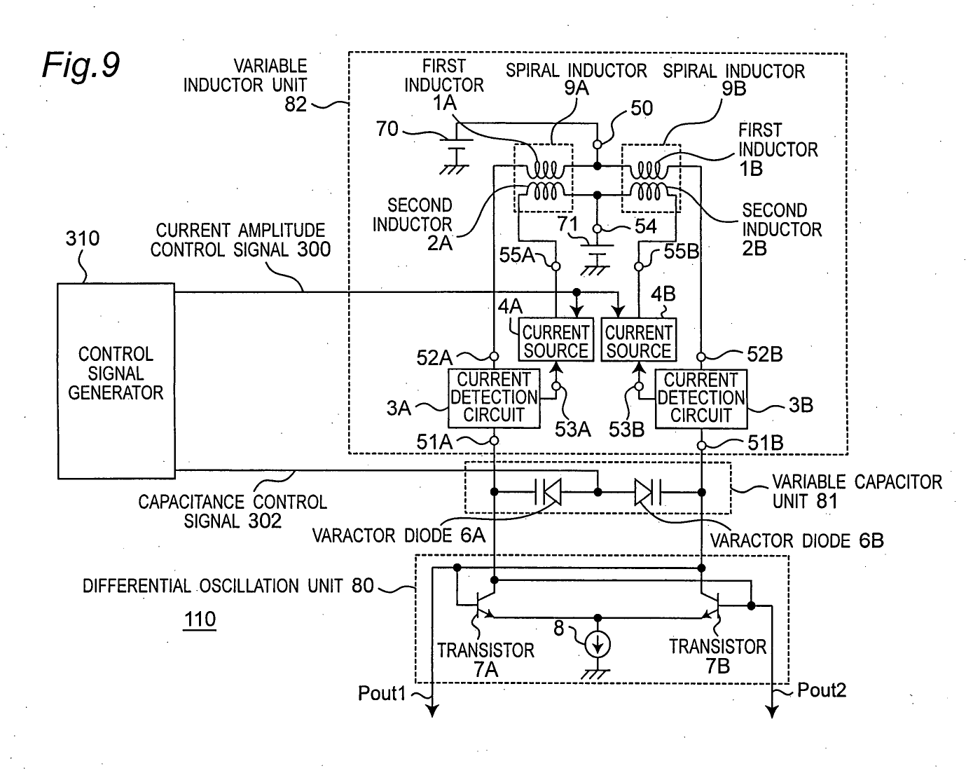

FIG. 9 is a block diagram of a voltage-controlled oscillator 110 according to this second embodiment of the invention.

As shown in FIG. 9, the voltage-controlled oscillator 110 comprises a differential oscillation unit 80 having transistors 7A and 7B, a variable capacitor unit 81 that uses varactor diodes 6A and 6B as variable capacitance elements, and a variable inductor unit 82 having spiral inductors 9A and 9B. The differential oscillation unit 80 oscillates using the inductance-capacitance parallel resonance circuit comprising variable inductor unit 82 and variable capacitor unit 81 as the load.

In the differential oscillation unit 80 the transistors 7A and 7B are connected with the base of one connected to the collector of the other, and the output signals Pout1 and Pout2 of the voltage-controlled oscillator 110 output from these two nodes. The emitters of transistors 7A and 7B go to ground through constant-current source 8. This cross connection of the collectors and bases of the two transistors renders a positive feedback operation that oscillates at the resonance frequency of the inductance-capacitance parallel resonance circuit including the variable inductor unit 82 and variable capacitor unit 81.

Two transistors are used as the differential oscillation unit 80 in this second embodiment of the invention, but the same effect can be achieved using two MOS transistors.

The anodes of the varactor diodes 6A and 6B in the variable capacitor unit 81 are connected to each other, and capacitance control signal 302 is input to this node. The cathodes of the varactor diodes 6A and 6B are connected to the collectors of transistors 7A and 7B and to nodes 51A and 51B, respectively. The voltage applied to both ends of the varactor diodes 6A and 6B varies according to the capacitance control signal 302, and the capacitance of the variable capacitor unit 81 is thus continuously variable.

The variable inductor unit 82 comprises two inductor units 100 shown in FIG. 2 in a differential arrangement. The first inductor 1 of the inductor unit 100 shown in FIG. 2 corresponds to first inductors 1A and 1B in the variable inductor unit 82 shown in FIG. 9, the second inductor 2 corresponds to second inductors 2A and 2B, the spiral inductor 9 corresponds to spiral inductors 9A and 9B, the current detection circuit 3 corresponds to current detection circuits 3A and 3B, and the current source 4 corresponds to current sources 4A and 4B. In addition, node 51 corresponds to nodes 51A and 51B, node 52 corresponds to nodes 52A and 52B, node 53 corresponds to nodes 53A and 53B, and node 55 corresponds to nodes 55A and 55B. Note, further, that node 50 and node 54 in FIG. 2 are connected to DC power sources 70 and 71 in FIG. 9.

The current flowing through first inductors 1A and 1B also flows between node 52A and node 51A, and node 52B and node 51B, through current detection circuits 3A and 3B, and the frequency, phase, and current amplitude of these currents are detected by the current detection circuits 3A and 3B. The current sources 4A and 4B generate current signals of the same frequency, same phase, and current amplitude of a predetermined current-amplitude ratio K1 to the current detected by the current detection circuits 3A and 3B. The resulting current signals flow through node 54 and nodes 55A and 55B to second inductors 2A and 2B.

The value of the current-amplitude ratio K1 is positive, negative, or zero, and is constant relative to the current amplitude of the input current, but also varies according to the current amplitude control signal 300 input to both current sources 4A and 4B.

The first inductors 1A and 1B and second inductors 2A and 2B constituting spiral inductors 9A and 9B, respectively, are disposed to positions that are magnetically coupled by mutual induction. Depending on the sign of the current-amplitude ratio K1, the magnetic flux produced by the second inductors 2A and 2B works to increase or decrease the magnetic flux produced by the first inductors 1A and 1B. In this embodiment of the invention the second inductors 2A and 2B work to increase the magnetic flux from the first inductors 1A and 1B when current-amplitude ratio K1 is positive, and to decrease the magnetic flux of first inductors 1A and 1B when the current-amplitude ratio K1 is negative.

The amplitude of the current signals flowing through the second inductors 2A and 2B varies continuously according to the current amplitude control signal 300 input to the current sources 4A and 4B in the variable inductor unit 82 thus arranged. As a result, the current-amplitude ratio K1 of the current signal or the amplitude of the current signal flowing through the second inductors 2A and 2B can be continuously controlled by the current amplitude control signal 300. The apparent inductance of the first inductors 1A and 1B reflecting the mutual induction of the magnetic flux from the second inductors 2A and 2B on the magnetic flux produced by the first inductors 1A and 1B is the inductance of the variable inductor unit 82, and the inductance of the variable inductor unit 82 changes continuously and can be set as desired by the current amplitude control signal 300.

Furthermore, when current-amplitude ratio K1 is positive, the inductance of the variable inductor unit 82 increases and the resistance of the first inductors 1A and 1B does not change. As a result, the Q of the inductance of the variable inductor unit 82 increases compared with the first inductors 1A and 1B alone.

Note also that the capacitance control signal 302 and the current amplitude control signal 300 are generated by the control signal generator 310.

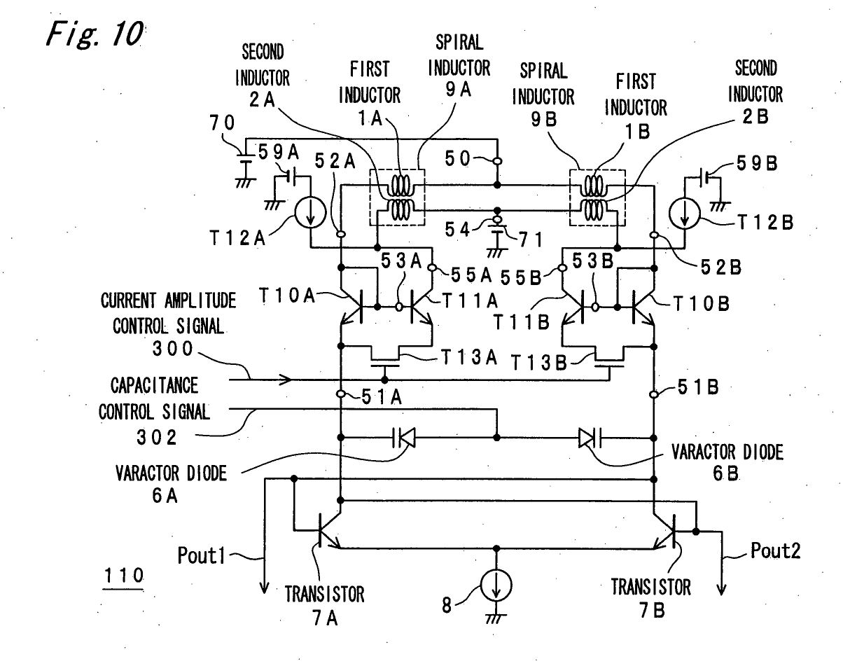

FIG. 10 is a circuit diagram of the voltage-controlled oscillator 110 according to the second embodiment shown in FIG. 9.

If the circuitry of the inductor unit 100 shown in FIG. 2 is as shown in FIG. 5C, the circuitry of the voltage-controlled oscillator 110 shown in FIG. 9 is as shown in FIG. 10.

First Variation of the Second Embodiment

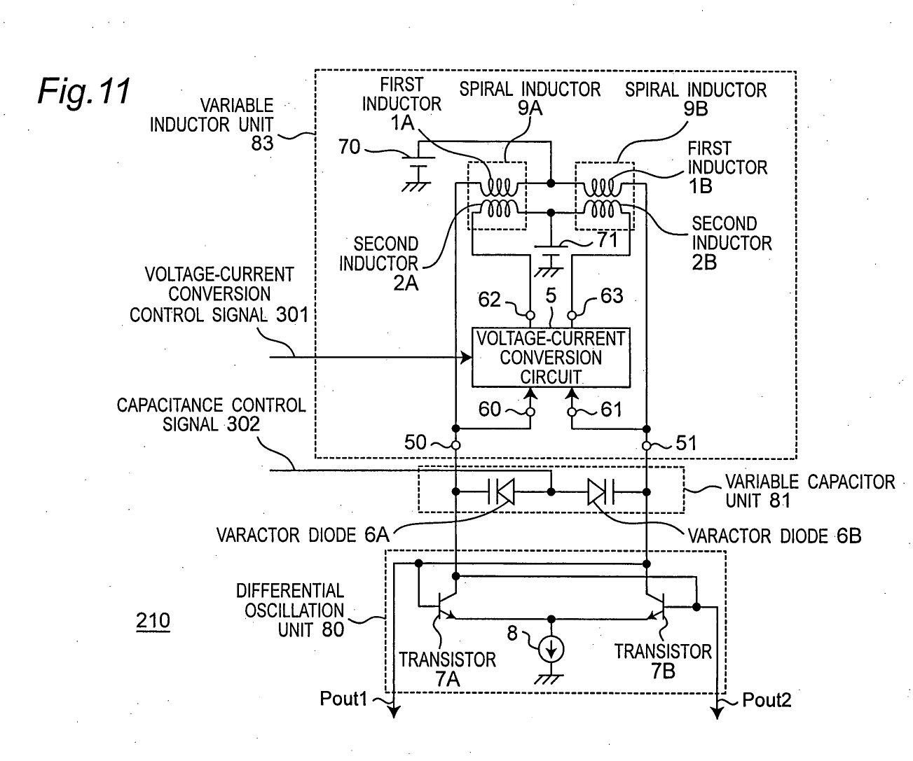

FIG. 11 is a block diagram of the voltage-controlled oscillator 210 in a first variation of the second embodiment of the invention.

This voltage-controlled oscillator 210 comprises a differential oscillation unit 80 composed of transistors 7A and 7B, a variable capacitor unit 81 that uses varactor diodes 6A and 6B as variable capacitance elements, and a variable inductor unit 83 having spiral inductors 9A and 9B. The differential oscillation unit 80 oscillates using the inductance-capacitance parallel resonance circuit comprising variable inductor unit 83 and variable capacitor unit 81 as the load.

While the variable inductor unit 82 of the voltage-controlled oscillator 110 shown in FIG. 9 comprises two inductor units 100 shown in FIG. 2 in a differential arrangement, the variable inductor unit 83 of the voltage-controlled oscillator 210 in FIG. 11 is basically a differential arrangement using the inductor unit 200 shown in FIG. 4. In FIG. 4 the first inductor 1 and second inductor 2 are divided equally at the midpoint of their inductance. In the voltage-controlled oscillator 210 shown in FIG. 11, these are replaced by first inductors 1A and 1B and second inductors 2A and 2B with the midpoints thereof connected to DC power sources 70 and 71, respectively.

The voltage between node 50 and node 51 at the ends of first inductors 1A and 1B is input to voltage-current conversion circuit 5. The voltage-current conversion circuit 5 generates a current signal having a current amplitude of a predetermined voltage-current conversion ratio K2 and the same frequency as the input voltage, and this current signal flows through node 62 and node 63 to second inductors 2A and 2B. The value of the voltage-current conversion ratio K2 is positive, negative, or zero, and is constant relative to the voltage amplitude of the input voltage, but varies according to the voltage-current conversion control signal 301 input to the voltage-current conversion circuit 5.

The first inductor 1A and second inductor 2A constituting spiral inductor 9A, and the first inductor 1B and second inductor 2B constituting spiral inductor 9B, are disposed to positions that are magnetically coupled by mutual induction. Depending on the sign of the voltage-current conversion ratio K2, the magnetic flux produced by the second inductors 2A and 2B works to increase or decrease the magnetic flux produced by the first inductors 1A and 1B. In this embodiment of the invention the magnetic flux increases when voltage-current conversion ratio K2 is positive, and decreases when the voltage-current conversion ratio K2 is negative.

In the variable inductor unit 83 thus comprised, the amplitude of the current signals flowing to the second inductors 2A and 2B varies continuously according to the voltage-current conversion control signal 301 input to the voltage-current conversion circuit 5. As a result, the voltage-current conversion ratio K2 of the current signals or the amplitude of the current signals flowing to the second inductors 2A and 2B can be continuously controlled based on the voltage-current conversion control signal 301. The apparent inductance of the first inductors 1A and 1B reflecting the mutual induction of the magnetic flux from the second inductors 2A and 2B on the magnetic flux from the first inductors 1A and 1B is the inductance of the variable inductor unit 83, and varies continuously and can be set as desired by the voltage-current conversion control signal 301.

Furthermore, when voltage-current conversion ratio K2 is positive, the inductance of the variable inductor unit 83 increases and the resistance of the first inductors 1A and 1B does not change. As a result, the Q of the inductance of the variable inductor unit 83 increases compared with first inductors 1A and 1B alone.

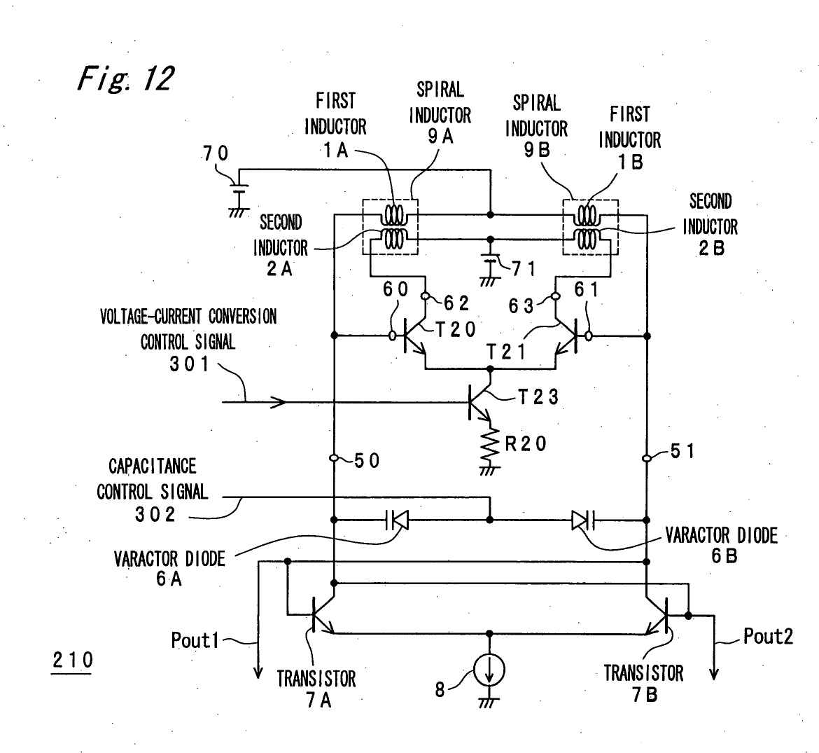

FIG. 12 is a circuit diagram of the voltage-controlled oscillator 210 in the first variation of the second embodiment shown in FIG. 11.

If the circuit design of the inductor unit 200 shown in FIG. 4 is as shown in FIG. 6B, the circuitry of the voltage-controlled oscillator 210 shown in FIG. 11 is as shown in FIG. 12.

Second Variation of the Second Embodiment

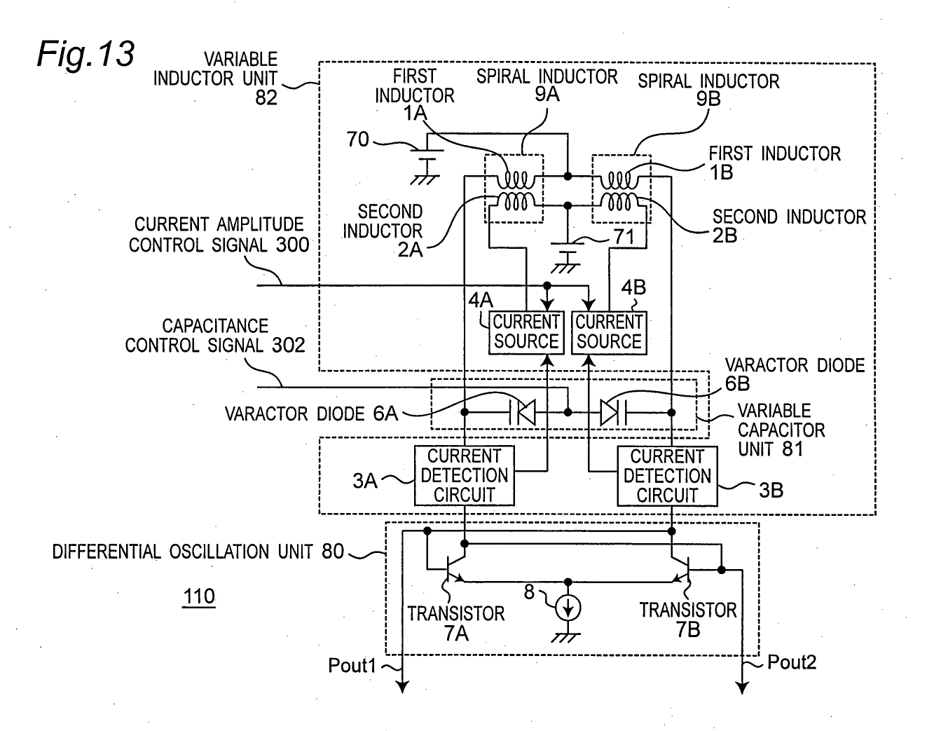

FIG. 13 is a block diagram of a voltage-controlled oscillator 110 according to a second variation of the second embodiment.

This voltage-controlled oscillator 110 differs from the voltage-controlled oscillator 110 shown in FIG. 9 in that the current detection circuits 3A and 3B are moved to between the variable capacitor unit 81 and differential oscillation unit 80. In the voltage-controlled oscillator 110 shown in FIG. 9 the current detection circuits 3A and 3B are inserted in series to the inductance-capacitance parallel resonance circuit formed by the variable inductor unit 82 and variable capacitor unit 81, and the Q of the resonance can be degraded by the impedance characteristic of the current detection circuits 3A and 3B. With the voltage-controlled oscillator 110 shown in FIG. 13, however, the current detection circuits 3A and 3B are disposed outside the inductance-capacitance parallel resonance circuit to detect the differential resonance current, thereby affording a constant good Q.

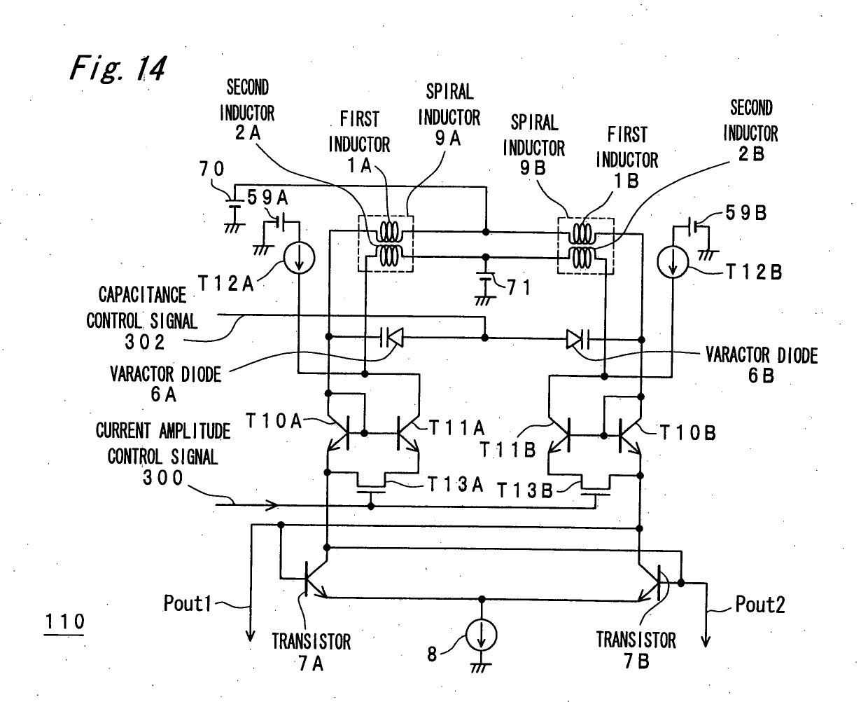

FIG. 14 is a circuit diagram of a voltage-controlled oscillator 110 according to a second variation of the second embodiment of the invention.

In the voltage-controlled oscillator 110 shown in FIG. 14 the location of transistors T10A and T10B corresponding to current detection circuits 3A and 3B in FIG. 10 is moved to between varactor diodes 6A and 6B and transistors 7A and 7B based on the arrangements shown in FIG. 9 and FIG. 13.

Third Variation of the Second Embodiment

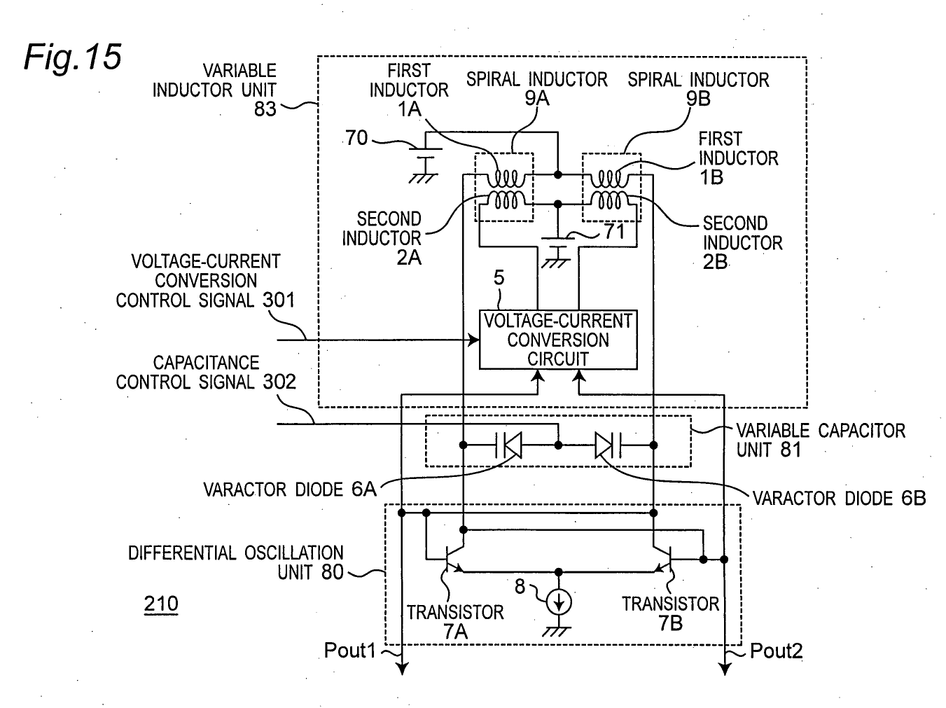

FIG. 15 is a block diagram of a voltage-controlled oscillator 210 in a third variation of the second embodiment.

This voltage-controlled oscillator 210 differs from the voltage-controlled oscillator 210 shown in FIG. 11 in that the positions where the voltage input to the voltage-current conversion circuit 5 through node 60 and node 61 is moved to the base of transistors 7A and 7B, respectively. In the voltage-controlled oscillator 210 shown in FIG. 11 the voltage-current conversion circuit 5 is inserted parallel to the inductance-capacitance parallel resonance circuit of variable inductor unit 83 and variable capacitor unit 81, and the Q of the resonance may be degraded by the impedance characteristic of the voltage-current conversion circuit 5. In the voltage-controlled oscillator 210 shown in FIG. 15, however, the voltage-current conversion circuit 5 is located outside the inductance-capacitance parallel resonance circuit and detects the resonance voltage of the differentially operating differential oscillation unit 80, thereby always affording a good Q characteristic.

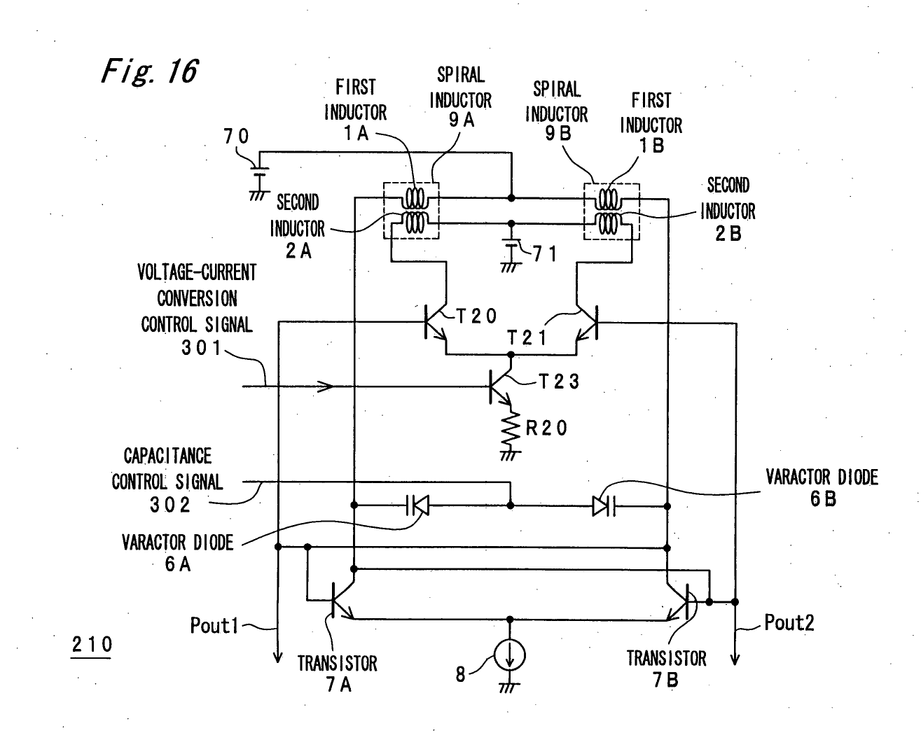

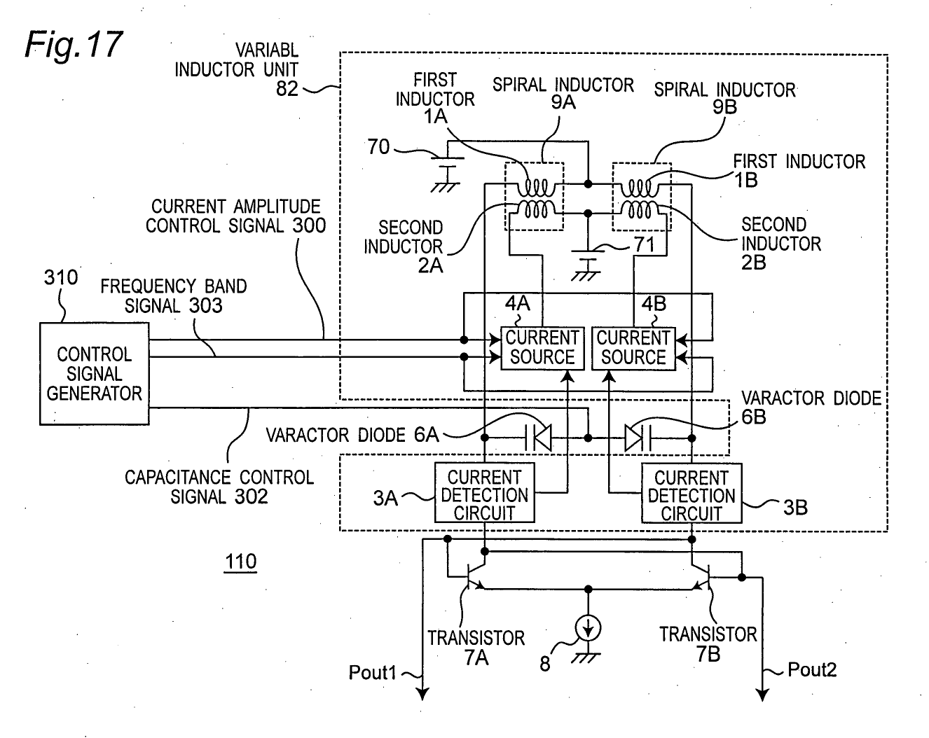

FIG. 16 is a circuit diagram of a voltage-controlled oscillator 210 according to the third variation of the second embodiment of the invention.

Based on the relationship between FIG. 11 and FIG. 15, the bases of transistors T20 and T21 corresponding to the positions where voltage is detected by the voltage-current conversion circuit 5 in FIG. 12 are connected to the bases of transistors 7A and 7B, respectively.

Fourth Variation of the Second Embodiment

FIG. 17 is a block diagram of a voltage-controlled oscillator 110 according to a fourth variation of the second embodiment.

This voltage-controlled oscillator 110 differs from the voltage-controlled oscillator 110 shown in FIG. 13 in that a frequency band signal 303 is input in addition to the current amplitude control signal 300 as a signal for controlling the current sources 4A and 4B. The current sources 4A and 4B can control the amplitude of the current signals or the current-amplitude ratio K1 of the current signals flowing to second inductors 2A and 2B continuously by the current amplitude control signal 300 and in steps by the frequency band signal 303. As a result, the inductance of the variable inductor unit 82 varies continuously according to the current amplitude control signal 300 and varies in steps according to the frequency band signal 303. The inductance of the variable inductor unit 82 can thus be set as desired.

The frequency band signal 303, current amplitude control signal 300, and capacitance control signal 302 are generated by the control signal generator 310.

Fifth Variation of the Second Embodiment

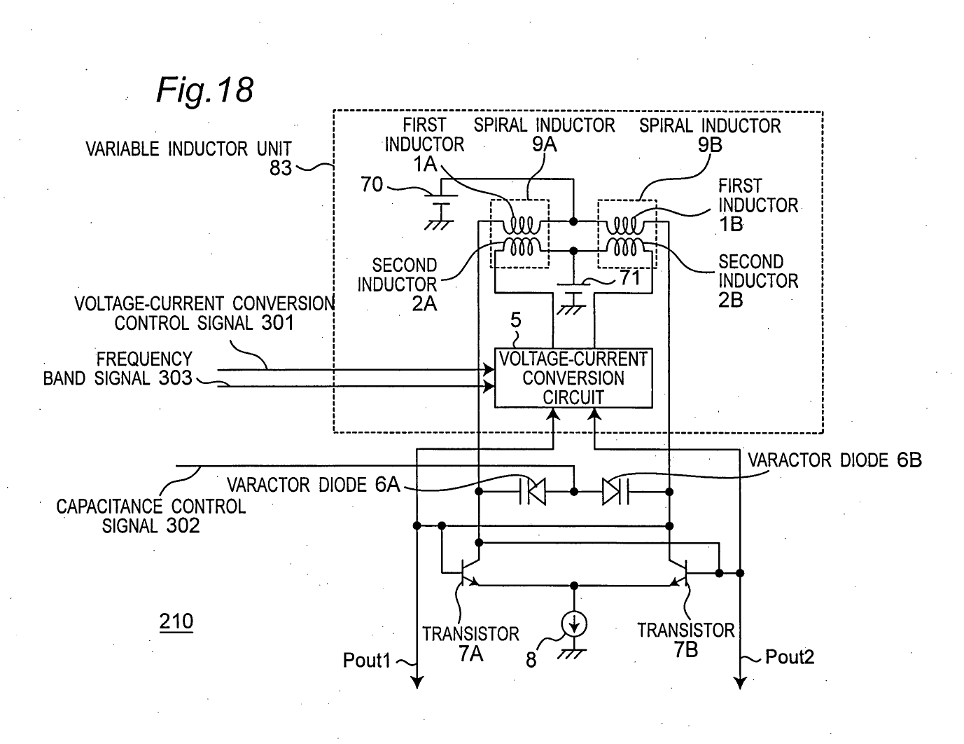

FIG. 18 is a block diagram of a voltage-controlled oscillator 210 in a fifth variation of the second embodiment.

This voltage-controlled oscillator 210 differs from the voltage-controlled oscillator 210 shown in FIG. 15 in that frequency band signal 303 is input in addition to the voltage-current conversion control signal 301 as a signal controlling the voltage-current conversion circuit 5. The voltage-current conversion circuit 5 varies the voltage-current conversion ratio K2 of the current signals or the amplitude of the current signals flowing to the second inductors 2A and 2B continuously according to the voltage-current conversion control signal 301 and in steps according to the frequency band signal 303. As a result, the inductance of the variable inductor unit 83 varies continuously according to the voltage-current conversion control signal 301 and in steps according to the frequency band signal 303. The inductance of the variable inductor unit 83 can thus be set as desired.

Sixth Variation of the Second Embodiment

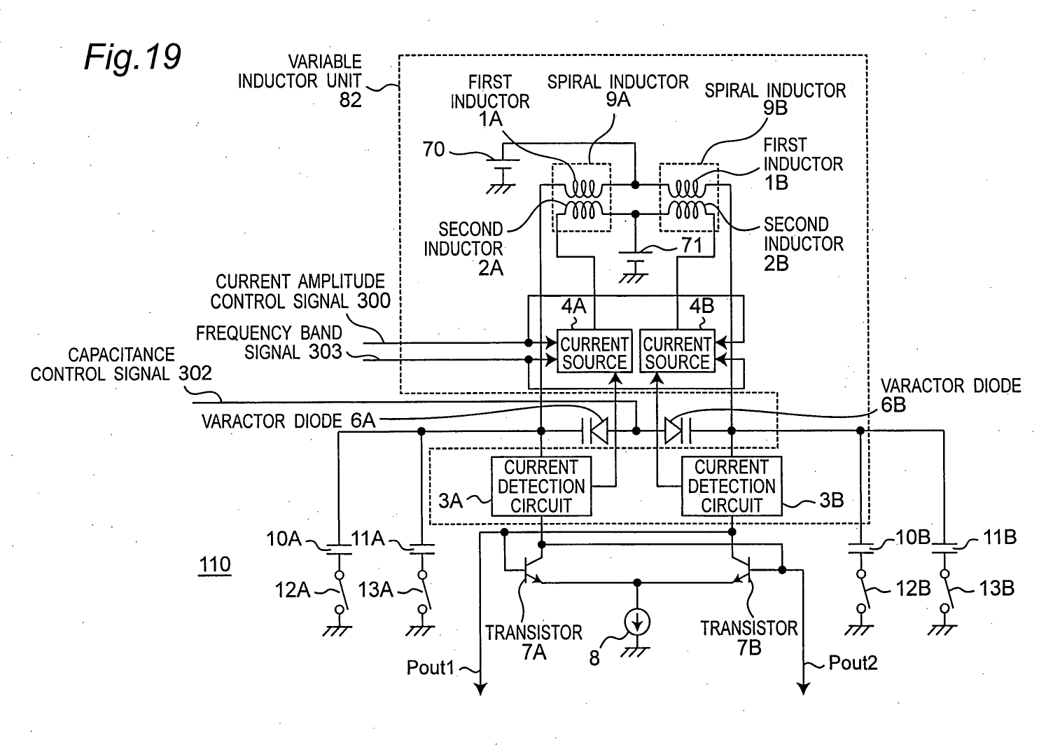

FIG. 19 is a block diagram of a voltage-controlled oscillator 110 according to a sixth variation of the second embodiment.

This voltage-controlled oscillator 110 differs from the voltage-controlled oscillator 110 shown in FIG. 17 in that fixed capacitors 10A, 11A, and 10B, 11B are disposed parallel to varactor diodes 6A and 6B, and switches 12A, 13A and 12B, 13B are disposed in series to these fixed capacitors. Because the voltage-controlled oscillator 110 has a differential arrangement, the capacitance of fixed capacitors 10A, 11A and fixed capacitors 10B, 11B is the same, and switches 12A, 13A and switches 12B, 13B operate in conjunction with each other.

By appropriately switching fixed capacitors 10A, 11A, the capacitance can be varied in four steps. By combining the continuous variation function of the varactor diodes 6A and 6B with the stepping variation and continuous variation functions of the variable inductor unit 82, the resonance frequency can be varied without greatly changing the inductance-capacitance ratio. As a result, the oscillation frequency band is wider, and a stable oscillation characteristic can be achieved over a wide frequency range. Variable capacitance elements of which the capacitance can be controlled by the voltage of a varactor diode, for example, can be used instead of fixed capacitors 10A, 11A, 10B, 11B and switches 12A, 13A, 12B, 13B to switch the fixed capacitors.

Seventh Variation of the Second Embodiment

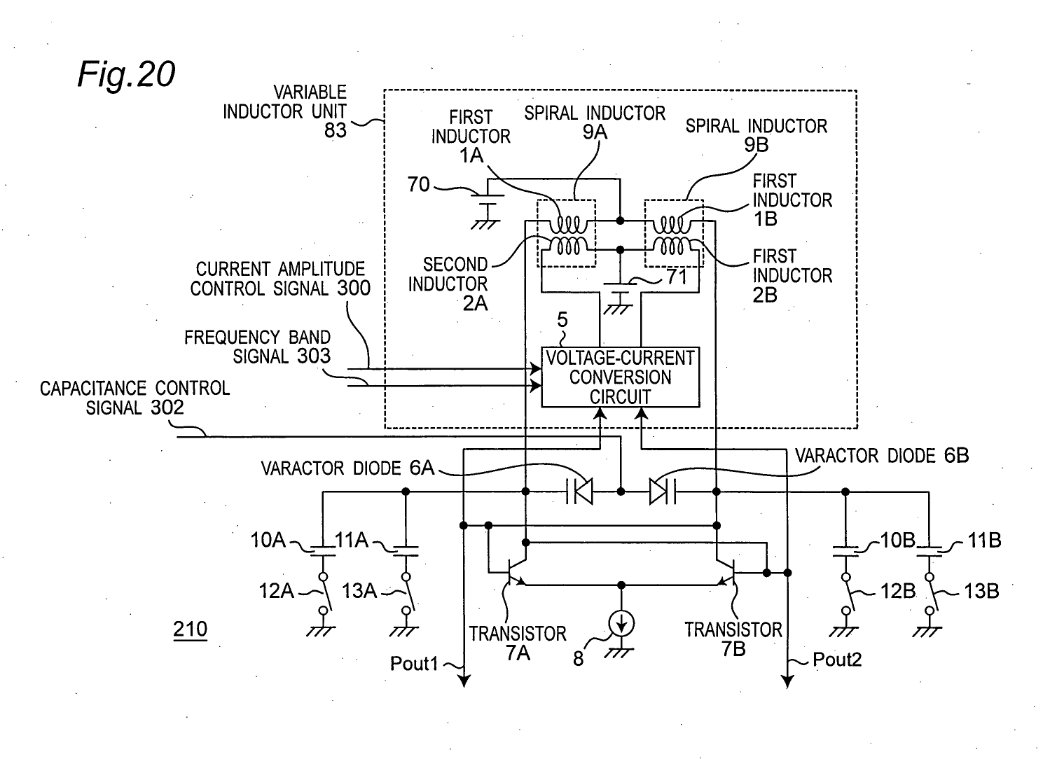

FIG. 20 is a block diagram of a voltage-controlled oscillator 210 according to a seventh variation of the second embodiment.

This voltage-controlled oscillator 210 differs from the voltage-controlled oscillator 210 shown in FIG. 18 in that fixed capacitors 10A, 11A, and 10B, 11B are disposed parallel to varactor diodes 6A and 6B, and switches 12A, 13A and 12B, 13B are disposed in series to these fixed capacitors. Because the voltage-controlled oscillator 210 has a differential arrangement, the capacitance of fixed capacitors 10A, 11A and fixed capacitors 10B, 11B is the same, and switches 12A, 13A and switches 12B, 13B operate in conjunction with each other.

By appropriately switching fixed capacitors 10A, 11A, the capacitance can be varied in four steps. By combining the continuous variation function of the varactor diodes 6A and 6B with the stepping variation and continuous variation functions of the variable inductor unit 83, the resonance frequency can be varied without greatly changing the inductance-capacitance ratio. As a result, the oscillation frequency band is wider, and a stable oscillation characteristic can be achieved over a wide frequency range. Variable capacitance elements of which the capacitance can be controlled by the voltage of a varactor diode, for example, can be used instead of fixed capacitors 10A, 11A, 10B, 11B and switches 12A, 13A, 12B, 13B to switch the fixed capacitors.

Oscillation Frequency Characteristic in the Second Embodiment

Factors affecting the oscillation frequency of the voltage-controlled oscillator are described below.

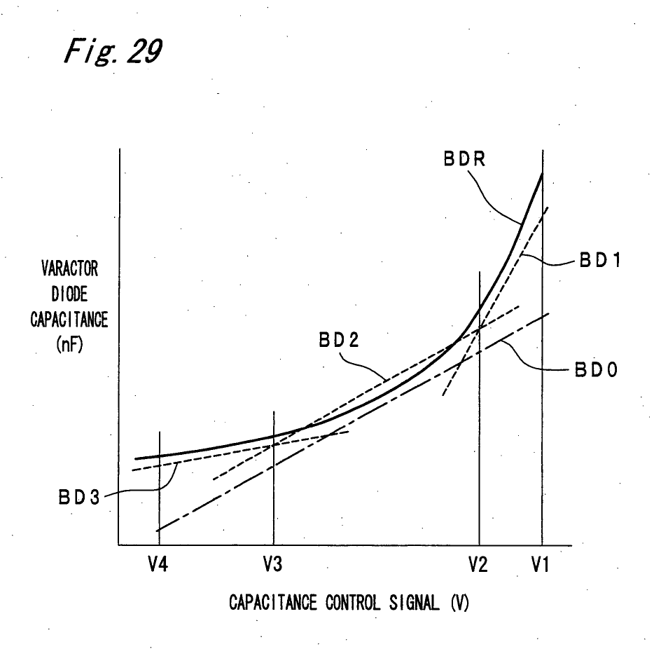

FIG. 29 shows the relationship between the capacitance of the varactor diode and capacitance control signal 302. Because both cathodes of the varactor diodes 6A and 6B are connected to DC power source 70, the voltage applied to both ends of the varactor diodes 6A and 6B decreases as capacitance control signal 302 increases from V4 to V3, V2, V1. The capacitance characteristic representing the relationship between the capacitance of varactor diodes 6A and 6B and capacitance control signal 302 is ideally linear and rises to the right as denoted by dot-dash line BD0.

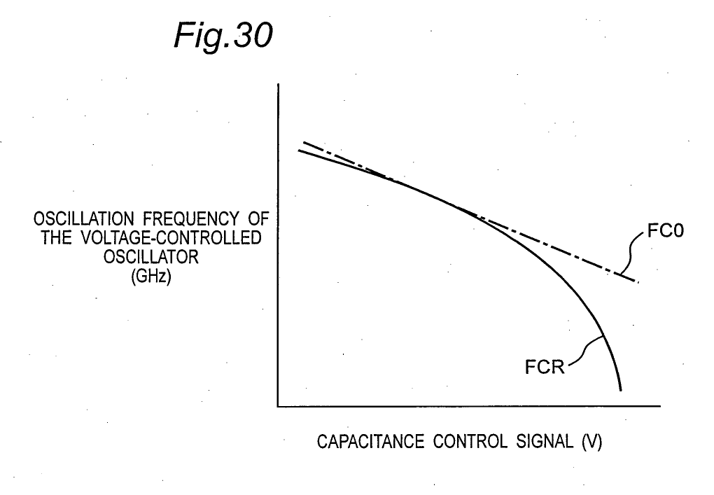

FIG. 30 schematically shows the relationship between the oscillation frequency of the voltage-controlled oscillator and capacitance control signal 302.

If half the inductance of the variable inductor unit is L and the capacitance of one of varactor diodes 6A and 6B is C, the ideal oscillation frequency fc of the differential operating voltage-controlled oscillator 110, 210 can be derived from equation (1).
fc=1/(2π*sqrt(L*C)) (1)

If the capacitance of varactor diodes 6A and 6B varies linearly on a right-rising curve as denoted by BD0 in FIG. 29, the oscillation frequency of the voltage-controlled oscillator ideally decreases linearly to the right as denoted by FC0 in FIG. 30.

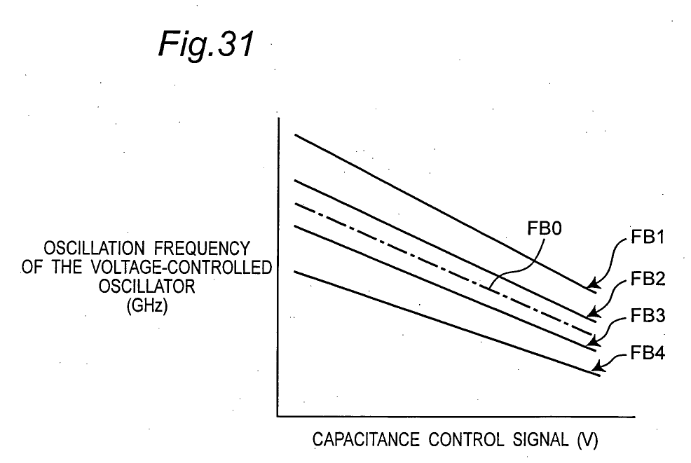

FIG. 31 schematically shows the relationship between the capacitance control signal 302 and the oscillation frequency of the voltage-controlled oscillator where the frequency band signal is a parameter. The ideal response corresponding to the ideal characteristic FC0 shown in FIG. 30 is line FB0, which represents the frequency band characteristic denoting the relationship when the frequency band signal is varied based on line FB0. If the inductance of the variable inductor unit is assumed to increase monotonically to frequency band signals FB1, FB2, FB3, FB4, four frequency bands can be rendered as shown in FIG. 31. As a result, the oscillation frequency band increases and operation can switch between a plurality of frequency bands, and the present invention can be applied in, for example, cell phones that use a plurality of frequency bands.

In practice, however, the capacitance of the varactor diode is nonlinear with respect to the capacitance control signal 302 as indicated by curve BDR in FIG. 29. As a result, the oscillation frequency of the voltage-controlled oscillator also varies nonlinearly to the capacitance control signal 302 as indicated by curve FCR in FIG. 30. The conversion gain Kv of the voltage-controlled oscillator is expressed as the degree of change in the oscillation frequency to the change in the capacitance control signal 302, but in this case varies dependently upon the value of the capacitance control signal 302. A PLL incorporating this voltage-controlled oscillator will exhibit an unstable lockup time and C/N characteristic depending on the oscillation frequency.

Solving the Nonlinearity of the Oscillation Frequency Characteristic

To solve this problem, the nonlinearity induced by the varactor diode as denoted by curve FCR in FIG. 30 is corrected by the inductance-changing function of the variable inductor unit. The temperature characteristic of the varactor diode and fixed capacitor is also corrected in the same way.

If VT (unit=volts) denotes the level of the capacitance control signal, FB is the number of the frequency band signal, and TM (unit=degrees) is temperature, the actual oscillation frequency fc1 can be derived from equation (2) as compares with the ideal oscillation frequency fc shown in equation (1).
fc1=1/(2π*sqrt(L*A1(VT)*A2(FB)*A3(TM)*C)) (2)

A1(VT), A2(FB), and A3(TM) are nonlinear functions that are uniquely determined by VT, FB, and TM, and represent the offset from the ideal capacitance, frequency band, and temperature characteristics. Capacitance C denotes the capacitance of the varactor diode or fixed capacitor, is offset from the ideal characteristic by nonlinearity and the temperature characteristic, and is (A1(VT)*A2(FB)*A3(TM))*C. In this case, the ideal oscillation frequency fc can be achieved as shown in equation (1) by changing the half inductance L of the variable inductor unit to L/(A1(VT)*A2(FB)*A3(TM)) as shown in equation (3).
fc=1/(2π*sqrt(L/(A1(VT)*A2(FB)*A3(TM))*(A1(VT)*A2(FB)*A3(TM))*C)) (3)

If the actual capacitance characteristic BDR shown in FIG. 29 is divided into three parts, the capacitance characteristic will be approximated by line BD1 of slope B1 when the capacitance control signal VT is in the range from V1 to V2, by line BD2 of slope B2 when VT is in the range from V2 to V3, and line BD3 of slope B3 when VT is in the range from V3 to V4. If B0 is the slope of the ideal characteristic BD0, the correction coefficient for the capacitance characteristic is defined by equations (4), (5), and (6).
A1(VT)=B0/B1 (V2≦VT≦V1) (4)
A1(VT)=B0/B2 (V3≦VT≦V2) (5)
A1(VT)=B0/B3 (V4≦VT≦V3) (6)
Linear approximation is used for correction coefficient A1 (VT) here, but a quadratic approximation or table based on the actual curve could be used.

The correction coefficient for the frequency band characteristic is as shown in equations (7), (8), and (9) where B1 is the slope of the line when the frequency band signal FB is FB1 in FIG. 31, B2 is the slope when frequency band signal FB is FB2, B3 is the slope when frequency band signal FB is FB3, and B0 is the slope for the ideal characteristic FB0.
A2(FB1)=B0/B1 (7)
A2(FB2)=B0/B2 (8)
A2(FB3)=B0/B3 (9)

The temperature characteristic is described next.

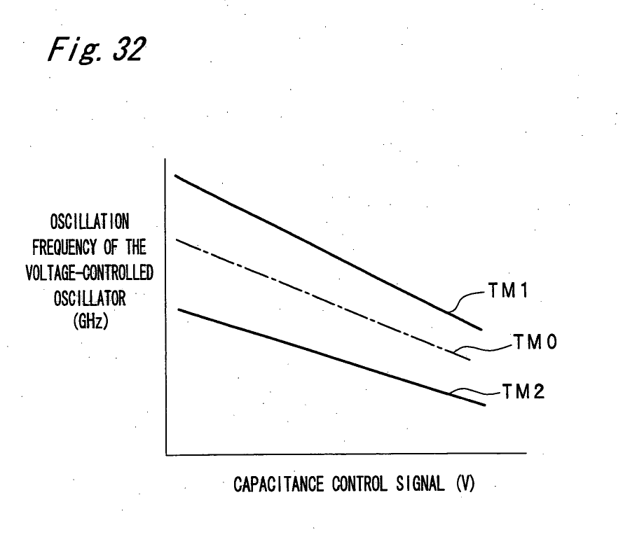

FIG. 32 schematically shows the relationship between the oscillation frequency of the voltage-controlled oscillator and capacitance control signal 302 using temperature as a parameter. The ideal temperature characteristic corresponding to ideal characteristic FC0 in FIG. 30 is line TM0 representing the values at a normal temperature of 25 degC. TM1 corresponds to a high temperature of 100 degC., and TM2 to a low temperature of −40 degC.

If B1 is the slope when temperature TM is TM1, B2 is slope when TM is TM2, and B0 is the slope of the ideal characteristic TM0, the temperature characteristic correction coefficient is as shown in equations (10) and (11).
A3(TM1)=B0/B1 (10)
A3(TM2)=B0/B2 (11)

This temperature characteristic correction is applied not only to the varactor diode, but also the fixed capacitors 10A, 11A, 10B, 11B shown in FIG. 19 and FIG. 20.

By correcting the half inductance L of the variable inductor unit to L/(A1(VT)*A2(FB)*A3(TM)) by the control signals, the nonlinearity of the varactor diode and the temperature characteristic of the varactor diode and fixed capacitors can be corrected to the ideal characteristic. Because the conversion gain Kv of the voltage-controlled oscillator is constant regardless of capacitance control signal 302, the lockup time and C/N characteristic of a PLL incorporating the voltage-controlled oscillator are constant to the oscillation frequency, and a stable oscillation characteristic can be achieved.

Eighth and Ninth Variations of the Second Embodiment

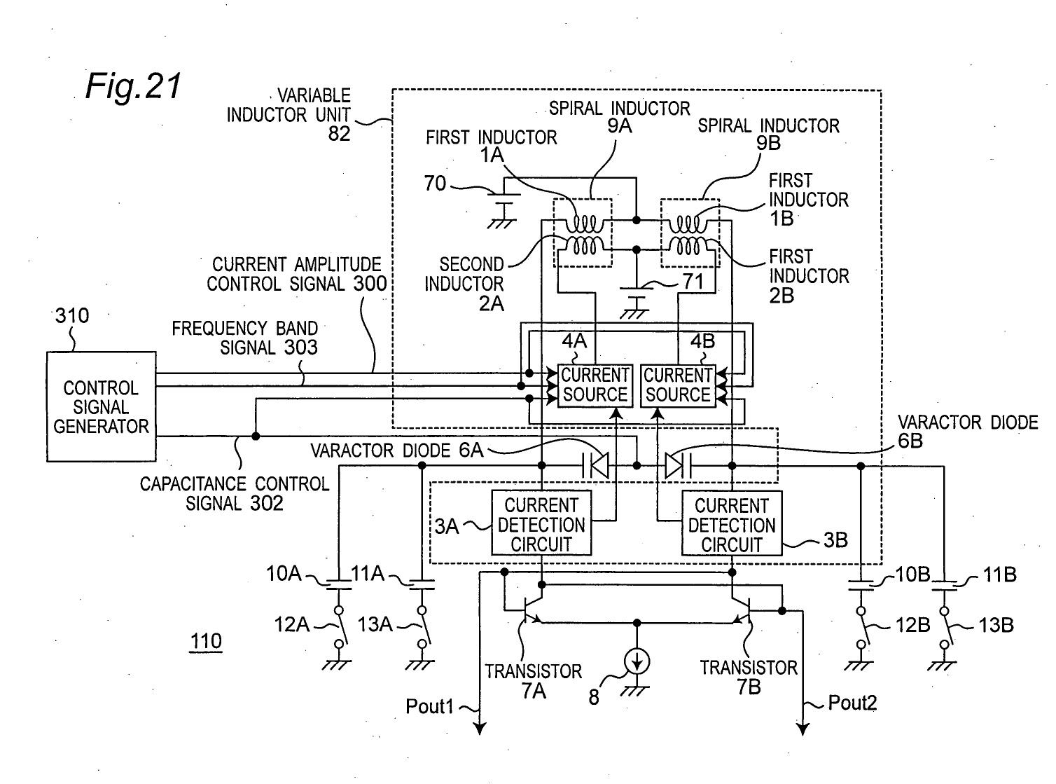

FIG. 21 is a block diagram of a voltage-controlled oscillator 110 according to an eighth variation of the second embodiment.

This voltage-controlled oscillator 110 differs from the voltage-controlled oscillator 110 shown in FIG. 19 in that capacitance control signal 302 is added as a signal controlling the current sources 4A and 4B. The actual capacitance characteristic BDR can be reflected in the inductance correction by storing the capacitance characteristics of the varactor diodes 6A and 6B to the capacitance control signal 302 as shown in FIG. 29 in a storage circuit and reading data from the storage circuit according to the capacitance control signal 302.

The ideal oscillation frequency characteristic can be achieved by multiplying the inductance of the variable inductor unit 82 by 1/(A1(VT)*A2(FB)) by capacitance control signal 302 and frequency band signal 303.

The capacitance control signal 302, current amplitude control signal 300, and frequency band signal 303 are produced by the control signal generator 310.

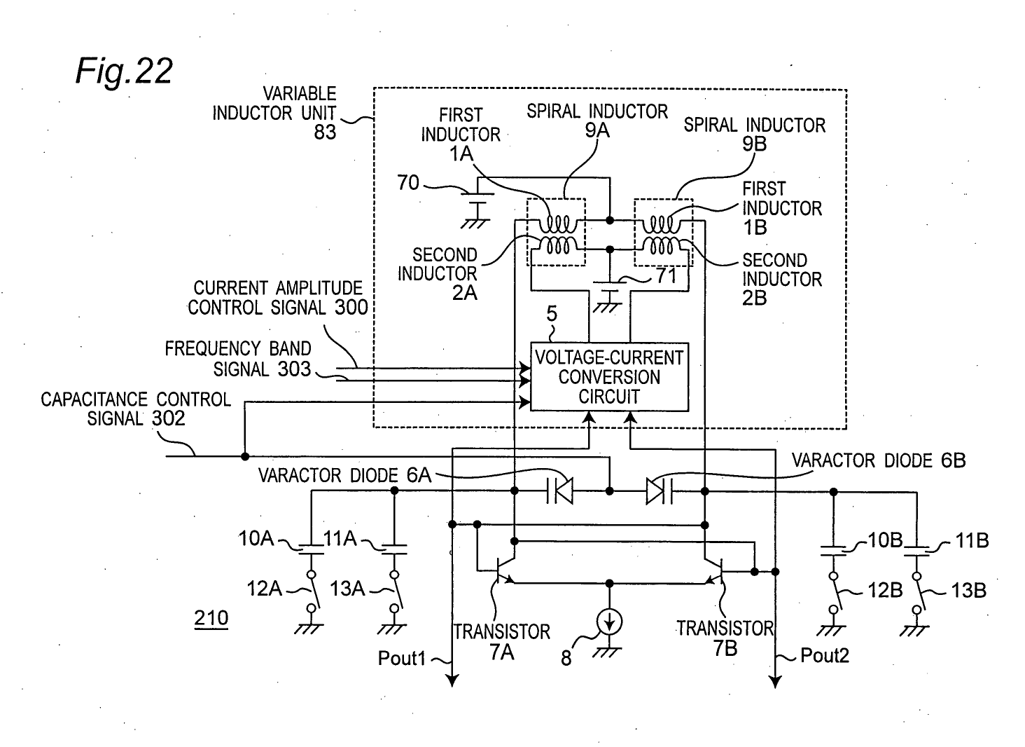

FIG. 22 is a block diagram of a voltage-controlled oscillator 210 according to a ninth variation of the second embodiment.

This voltage-controlled oscillator 210 differs from the voltage-controlled oscillator 210 shown in FIG. 20 in that capacitance control signal 302 is added as a signal controlling the voltage-current conversion circuit 5. The actual capacitance characteristic BDR can be reflected in the inductance correction by storing the capacitance characteristics of the varactor diodes 6A and 6B to the capacitance control signal 302 as shown in FIG. 29 in a storage circuit and reading data from the storage circuit according to the capacitance control signal 302.

The ideal oscillation frequency characteristic can be achieved by multiplying the inductance of the variable inductor unit 82 by 1/(A1(VT)*A2(FB)) by capacitance control signal 302 and frequency band signal 303.

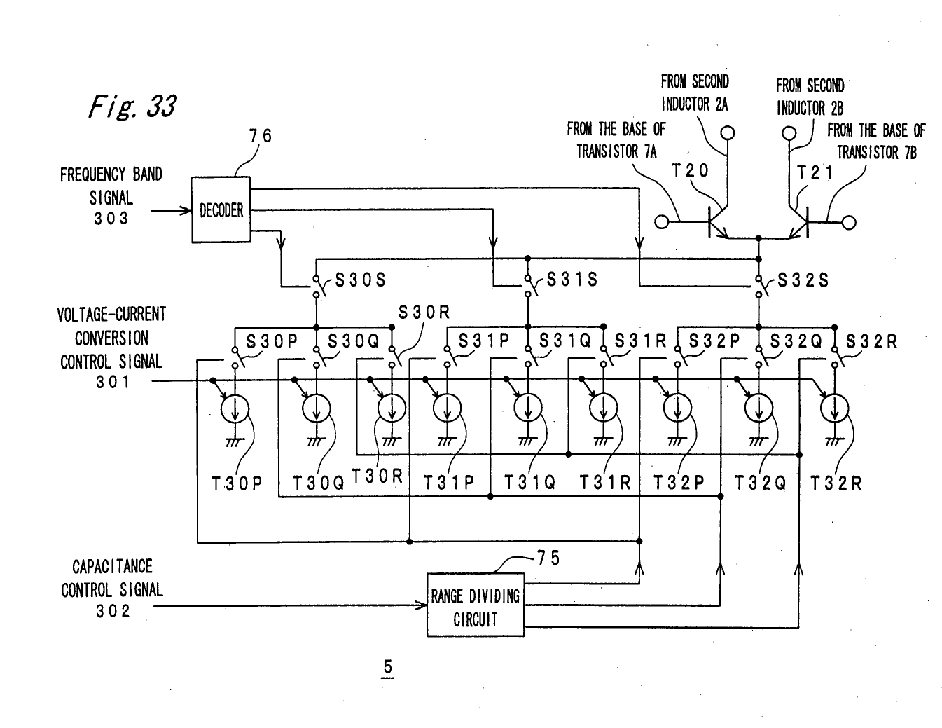

FIG. 33 is a circuit diagram of the voltage-current conversion circuit 5 in a ninth variation of the second embodiment.

As with the arrangement shown in FIG. 16, the bases of transistor T20 and transistor T21 in a differential arrangement are connected to the bases of transistors 7A and 7B, respectively, and the collectors are respectively connected to one side of second inductors 2A and 2B. A constant-current source is connected to the emitters of transistors T20 and T21. These nine constant-current sources are switched by the control signal.

The frequency band signal 303 uses two bits to denote three frequency bands, and the decoder 76 selects one of three constant-current source groups divided by switches S30S, S31S, and S32S. The capacitance control signal 302 is divided by range dividing circuit 75 into three bands from V1 to V2, V2 to V3, and V3 to V4 as shown in FIG. 29. The one of the three constant-current sources included in the group selected by the frequency band signal 303 is selected by switches S30P, S30Q, S30R, S31P, S31Q, S31R, S32P, S32Q, S32R.

The nine constant-current sources have a weighted current setting, and set the voltage-current conversion ratio K2 according to the current level. By appropriately switching these nine constant-current sources, the inductance of the variable inductor unit 83 is corrected to the inductance times 1/(A1(VT)*A2(FB)).

The voltage-current conversion control signal 301 is used to tune the nine constant-current sources or to correct another parameter.

Tenth and Eleventh Variations of the Second Embodiment

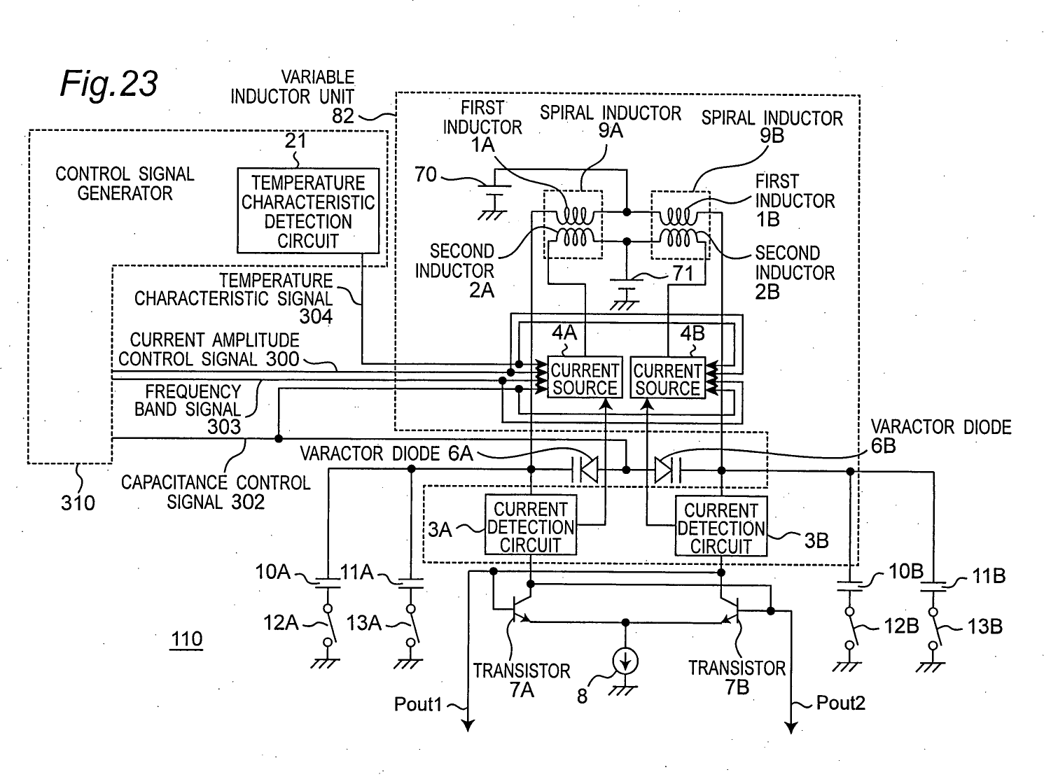

FIG. 23 is a block diagram of a voltage-controlled oscillator 110 according to a tenth variation of the second embodiment.

This voltage-controlled oscillator 110 differs from the voltage-controlled oscillator 110 shown in FIG. 21 in that a temperature characteristic signal 304 output from the temperature characteristic detection circuit 21 is added as a signal for controlling the current sources 4A and 4B.

The temperature characteristic detection circuit 21 detects the temperature characteristic of at least one of varactor diodes 6A and 6B and fixed capacitors 10A, 11A, 10B, 11B and inputs the result as temperature characteristic signal 304 to current sources 4A and 4B. Examples of the temperature characteristics of varactor diodes 6A and 6B are shown in FIG. 32.

The temperature characteristic of a diode in an IC device contained in the temperature characteristic detection circuit 21 is detected by way of example as a method for detecting the temperature characteristic.

The ideal oscillation frequency characteristic can thus be acquired using capacitance control signal 302, frequency band signal 303, and temperature characteristic signal 304 by multiplying the inductance of the variable inductor unit 82 by 1/(A1(VT)*A2(FB)*A3(TM)).

Note that the temperature characteristic detection circuit 21 is included in the control signal generator 310, and the temperature characteristic signal 304, current amplitude control signal 300, frequency band signal 303, and capacitance control signal 302 are generated by the control signal generator 310.

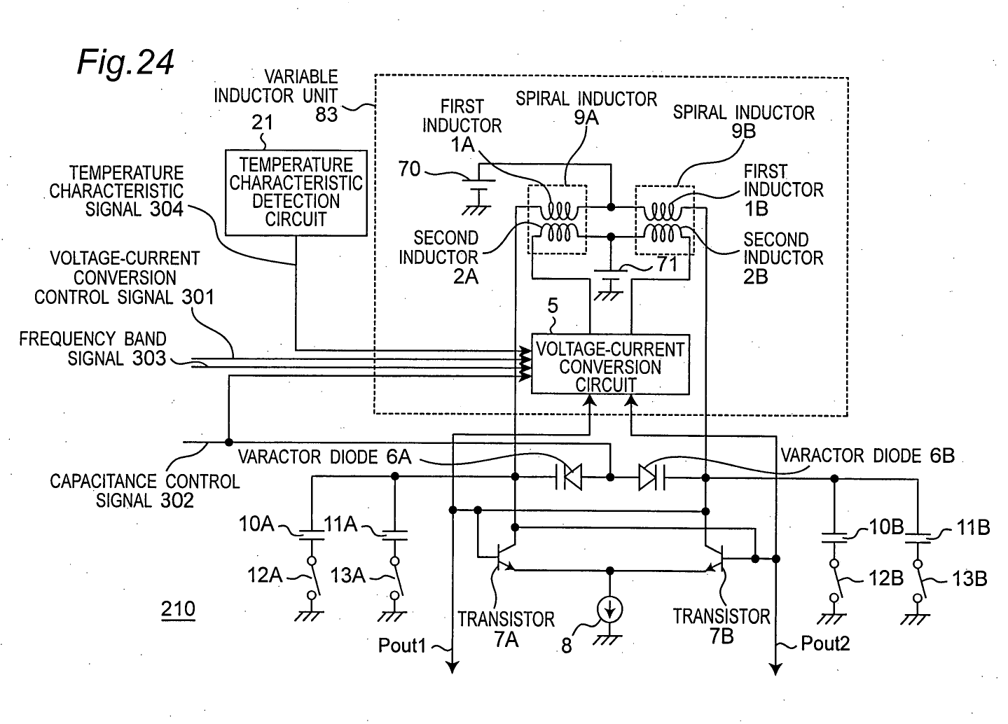

FIG. 24 is a block diagram of a voltage-controlled oscillator 210 according to an eleventh variation of the second embodiment.

This voltage-controlled oscillator 210 differs from the voltage-controlled oscillator 210 shown in FIG. 22 in that a temperature characteristic signal 304 output from the temperature characteristic detection circuit 21 is added as a signal for controlling the voltage-current conversion circuit 5.

The temperature characteristic detection circuit 21 detects the temperature characteristic of at least one of varactor diodes 6A and 6B and fixed capacitors 10A, 11A, 10B, 11B, and inputs the result as temperature characteristic signal 304 to current sources 4A and 4B. Examples of the temperature characteristics of varactor diodes 6A and 6B are shown in FIG. 32.

The temperature characteristic of a diode in an IC device contained in the temperature characteristic detection circuit 21 is detected by way of example as a method for detecting the temperature characteristic.

The ideal oscillation frequency characteristic can thus be acquired using capacitance control signal 302, frequency band signal 303, and temperature characteristic signal 304 by multiplying the inductance of the variable inductor unit 83 by 1/(A1(VT)*A2(FB)*A3(TM)).

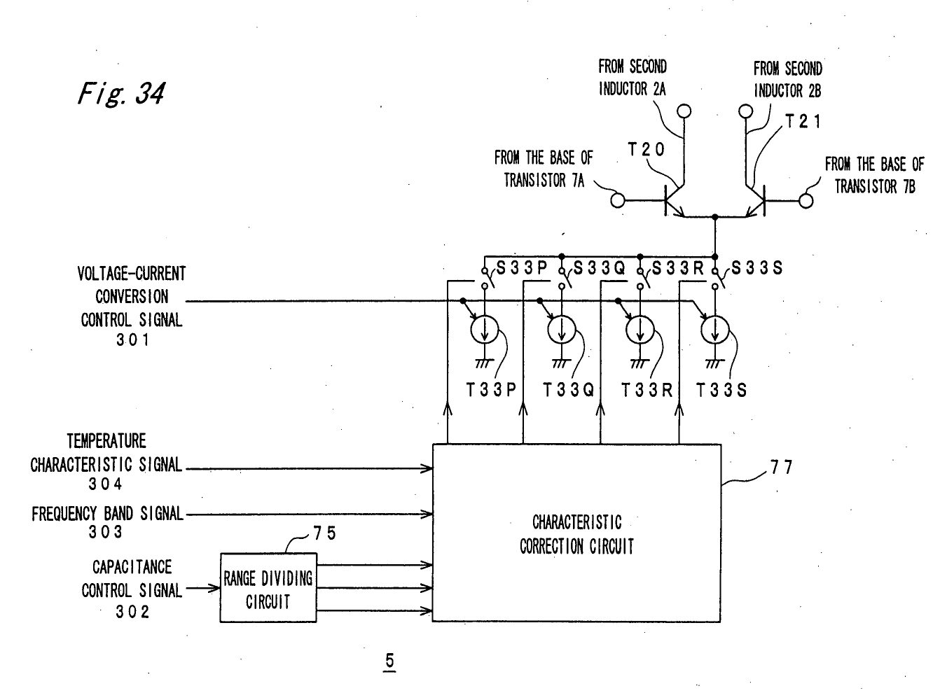

FIG. 34 is a circuit diagram of the voltage-current conversion circuit 5 in an eleventh variation of the second embodiment.

As with the arrangement shown in FIG. 16, the bases of transistor T20 and transistor T21 in a differential arrangement are connected to the bases of transistors 7A and 7B, respectively, and the collectors are respectively connected to one side of second inductors 2A and 2B. A constant-current source is connected to the emitters of transistors T20 and T21. These four constant-current sources are switched by the control signal.

The capacitance control signal 302 is divided by range dividing circuit 75 into three bands from V1 to V2, V2 to V3, and V3 to V4 as shown in FIG. 29, and is input as three signals, one of which is HIGH, to the characteristic correction circuit 77. Based on the signals from the range dividing circuit 75, the frequency band signal 303, and the temperature characteristic signal 304, the characteristic correction circuit 77 calculates correction coefficient 1/(A1(VT)*A2(FB)*A3(TM)) and outputs four control signals controlling switches S33P, S33Q, S33R, S33S.

The four constant-current sources T33P, T33Q, T33R, T33S have a weighted current setting, and set the voltage-current conversion ratio K2 according to the current level. By appropriately switching these nine constant-current sources, the inductance of the variable inductor unit 83 is corrected to the inductance times 1/(A1(VT)*A2(FB)*A3(TM)). At least one of switches S33P, S33Q, S33R, S33S is ON, and a plurality of these switches could be ON. By thus switching four constant-current sources, the inductance can be precisely corrected in fifteen steps.

The voltage-current conversion control signal 301 is used for precisely adjusting the four constant-current sources or for correcting another parameter.

Twelfth and Thirteenth Variations of the Second Embodiment

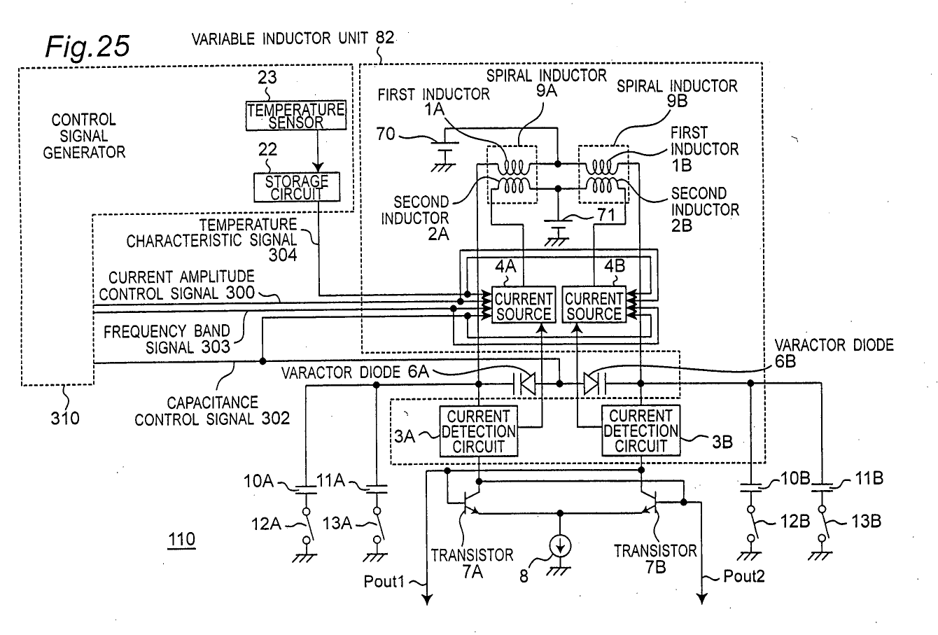

FIG. 25 is a block diagram of a voltage-controlled oscillator 110 according to a twelfth variation of the second embodiment.

This voltage-controlled oscillator 110 differs from the voltage-controlled oscillator 110 shown in FIG. 23 in that a temperature sensor 23 and storage circuit 22 are used instead of temperature characteristic detection circuit 21 to generate the temperature characteristic signal 304. The temperature sensor 23 detects the temperature of the varactor diodes 6A and 6B and fixed capacitors 10A, 11A, 10B, 11B, and inputs the detected temperature to the storage circuit 22, which stores the previously measured temperature characteristic. The change in capacitance at the detected temperature is generated as temperature characteristic signal 304 and input to the current sources 4A and 4B.

The ideal oscillation frequency characteristic can thus be acquired using capacitance control signal 302, frequency band signal 303, and temperature characteristic signal 304 by multiplying the inductance of the variable inductor unit 82 by 1/(A1(VT)*A2(FB)*A3(TM)).

Note that the temperature sensor 23 and storage circuit 22 are included in the control signal generator 310, and the temperature characteristic signal 304, current amplitude control signal 300, frequency band signal 303, and capacitance control signal 302 are generated by the control signal generator 310.

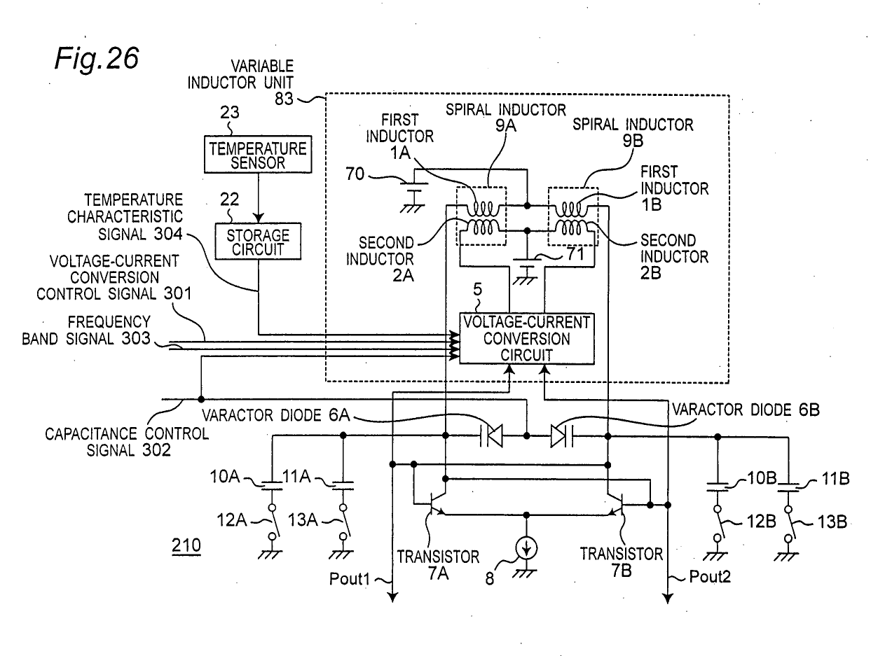

FIG. 26 is a block diagram of a voltage-controlled oscillator 210 according to a thirteenth variation of the second embodiment.

This voltage-controlled oscillator 210 differs from the voltage-controlled oscillator 210 shown in FIG. 24 in that the temperature characteristic signal 304 is generated by an arrangement comprising temperature sensor 23 and storage circuit 22 instead of temperature characteristic detection circuit 21.

The temperature sensor 23 detects the temperature of the varactor diodes 6A and 6B and fixed capacitors 10A, 11A, 10B, 11B, and inputs the detected temperature to the storage circuit 22, which stores the previously measured temperature characteristic. The change in capacitance at the detected temperature is generated as temperature characteristic signal 304 and input to the voltage-current conversion circuit 5.

The ideal oscillation frequency characteristic can thus be acquired using capacitance control signal 302, frequency band signal 303, and temperature characteristic signal 304 by multiplying the inductance of the variable inductor unit 83 by 1/(A1(VT)*A2(FB)*A3(TM)).

Fourteenth and Fifteenth Variations of the Second Embodiment

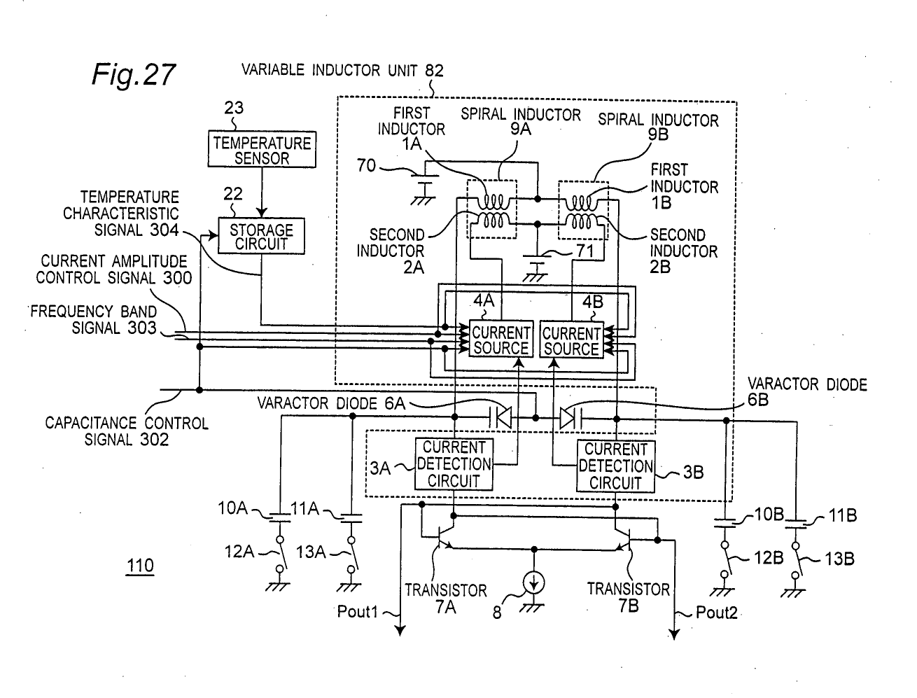

FIG. 27 is a block diagram of a voltage-controlled oscillator 110 according to a fourteenth variation of the second embodiment.

This voltage-controlled oscillator 110 differs from the voltage-controlled oscillator 110 shown in FIG. 25 in that capacitance control signal 302 is input in addition to the output signal from the temperature sensor 23 to the storage circuit 22. The storage circuit 22 stores the previously measured temperature characteristics of the varactor diodes 6A and 6B and fixed capacitors 10A, 11A, 10B, 11B. The change in capacitance determined by the detected temperature and the level of the capacitance control signal 302 is generated as temperature characteristic signal 304 based on input from the temperature sensor 23 and capacitance control signal 302 input, and the temperature characteristic signal 304 is input to the current sources 4A and 4B.

The ideal oscillation frequency characteristic can thus be acquired using capacitance control signal 302, frequency band signal 303, and temperature characteristic signal 304 by multiplying the inductance of the variable inductor unit 82 by 1/(A1(VT)*A2(FB)*A3(TM)).

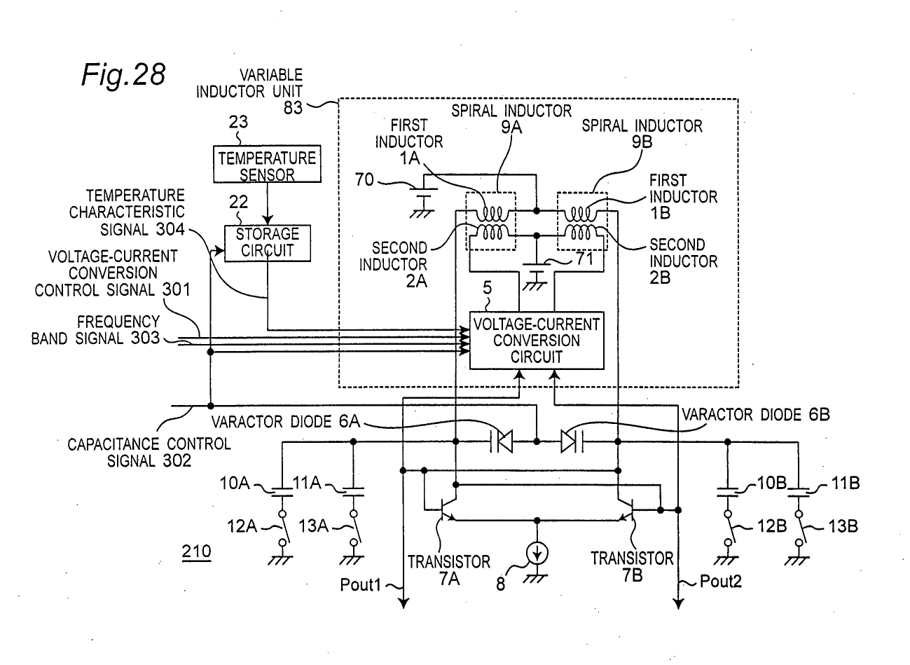

FIG. 28 is a block diagram of a voltage-controlled oscillator 210 according to a fifteenth variation of the second embodiment.

This voltage-controlled oscillator 210 differs from the voltage-controlled oscillator 210 shown in FIG. 26 in that capacitance control signal 302 is input in addition to the output signal from the temperature sensor 23 to the storage circuit 22. The storage circuit 22 stores the previously measured temperature characteristics of the varactor diodes 6A and 6B and fixed capacitors 10A, 11A, 10B, 11B. The change in capacitance determined by the detected temperature and the level of the capacitance control signal 302 is generated as temperature characteristic signal 304 based on input from the temperature sensor 23 and capacitance control signal 302 input, and the temperature characteristic signal 304 is input to the voltage-current conversion circuit 5.

The ideal oscillation frequency characteristic can thus be acquired using capacitance control signal 302, frequency band signal 303, and temperature characteristic signal 304 by multiplying the inductance of the variable inductor unit 83 by 1/(A1(VT)*A2(FB)*A3(TM)).

90-Degree Phase Inversion Shift Circuit

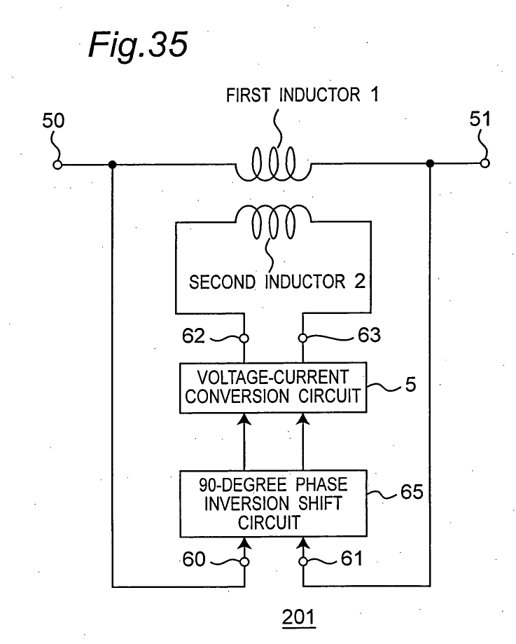

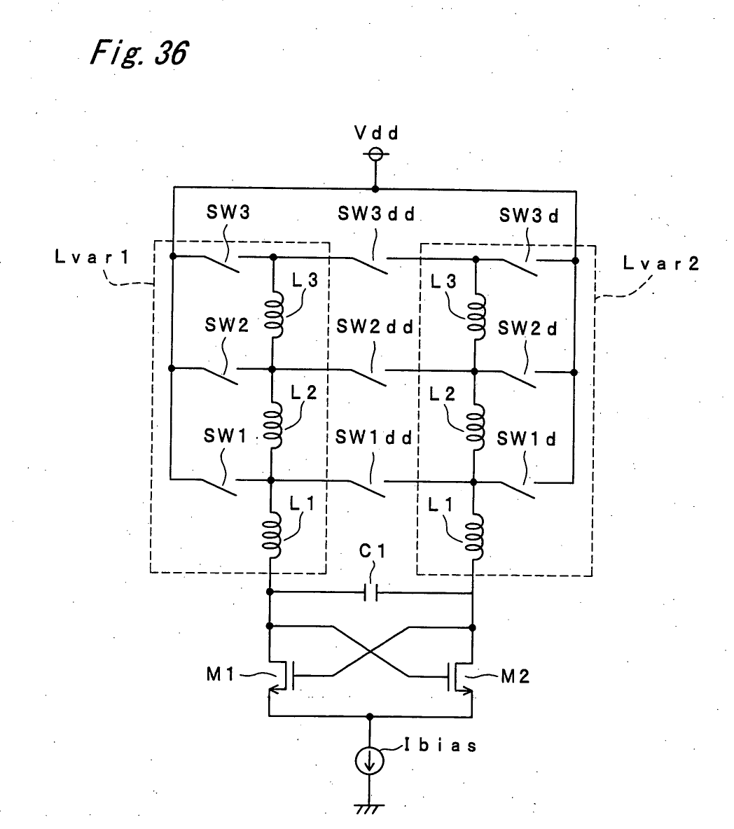

FIG. 35 is a block diagram of an inductor unit 201 comprising a 90-degree phase inversion shift circuit.

This inductor unit 201 differs from the inductor unit 200 shown in FIG. 3 in that a 90-degree phase inversion shift circuit 65 is inserted between nodes 60, 61 and voltage-current conversion circuit 5. The phase of the voltage at both ends is shifted 90 degrees to the current flowing through the first inductor 1. To enable more effective mutual induction between the second inductor 2 and the first inductor 1, the magnetic flux of the second inductor 2 is preferably the same phase as the flux of the first inductor 1. Using the 90-degree phase inversion shift circuit 65 to cause an inverse 90-degree phase shift, magnetic flux of the same phase as the first inductor 1 can be produced in the second inductor 2, and effective mutual induction can thus be assured.

Effect of the Second Embodiment

By rendering an inductor with a function for continuously varying the inductance, the oscillation frequency of the voltage-controlled oscillator can be accurately and precisely adjusted.

Furthermore, by continuously varying the oscillation frequency of the voltage-controlled oscillator, the voltage-controlled oscillator can be freely switched to operate at one of a plurality of frequency bands.

In addition, the nonlinearity of the varactor diode, and the temperature characteristic of the varactor diode and fixed capacitors can be corrected to the ideal characteristics. Because the conversion gain Kv of the voltage-controlled oscillator is constant irrespective of the capacitance control signal, the lockup time and C/N characteristic of the PLL incorporating this voltage-controlled oscillator are constant relative to the oscillation frequency, thus affording a stable oscillation characteristic.

The inductor unit of this invention also enables increasing the Q, and can therefore also improve the C/N ratio of the oscillation frequency of the voltage-controlled oscillator.

In addition, by rendering a function for varying the capacitance using a varactor diode, the resonance frequency can be changed without greatly varying the inductance to capacitance ratio. As a result, the oscillation frequency band is increased and a stable oscillation characteristic is achieved over a broad frequency range.

The second embodiment of the invention describes a preferred embodiment of a voltage-controlled oscillator according to the present invention, but the invention is not limited to application in a voltage-controlled oscillator and can also be used to the same effect in other types of oscillators using an inductor unit.

It will also be noted that the embodiments described above are used for illustration only, and the invention is not limited to the embodiments described above.

The present invention can be used in an inductor unit and in an oscillator that uses such an inductor unit.

Although the present invention has been described in connection with the preferred embodiments thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. An inductor unit comprising:
a first inductor;
a current signal generator operable to detect an electric signal denoting current flowing to the first inductor or the voltage at both ends of the first inductor, and to generate a current signal based on the electric signal; and
a second inductor that receives the current signal;
wherein the first inductor and second inductor are disposed to a predetermined magnetically coupled position and the inductance of the first inductor is set desirably.

2. The inductor unit described in claim 1, further comprising:
a control signal generator operable to generate a control signal;
wherein the current signal generator controls the amplitude of the current signal based on the control signal.

3. The inductor unit described in claim 1, wherein:
the first inductor is a spiral-shaped strip conductor formed on a first layer; and
the second inductor is a spiral-shaped strip conductor formed on a second layer.

4. The inductor unit described in claim 3, further comprising an insulation layer between the first layer and second layer.

5. The inductor unit described in claim 3, wherein the first layer and second layer are formed on a semiconductor substrate.

6. The inductor unit described in claim 5, wherein the second layer is formed on the semiconductor layer, and the first layer is formed above the second layer.

7. The inductor unit described in claim 1, wherein the first inductor and second inductor are spiral-shaped strip conductors formed on the same layer.

8. The inductor unit described in claim 7, wherein the first inductor and second inductor are formed on a semiconductor substrate.

9. An oscillator comprising:
an inductor unit comprising
a first inductor;
a current signal generator operable to detect an electric signal denoting current flowing to the first inductor or the voltage at both ends of the first inductor, and to generate a current signal based on the electric signal; and
a second inductor that receives the current signal;
wherein the first inductor and second inductor are disposed to a predetermined magnetically coupled position and the inductance of the first inductor is set desirably; and
a variable capacitance device connected to the inductor unit;
wherein the oscillator oscillates at an oscillation frequency determined by the inductance of the inductor unit and the capacitance of the variable capacitance device.

10. The oscillator described in claim 9, further comprising:
one or more fixed capacitors removably connected to the variable capacitance device;
wherein the oscillator oscillates at an oscillation frequency determined by the inductance of the inductor unit and the capacitance of the variable capacitance device and the fixed capacitor.

11. The oscillator described in claim 9, further comprising:
a control signal generator operable to generate a control signal;
wherein the current signal generator controls the amplitude of the current signal based on the control signal.

12. The oscillator described in claim 11, wherein:
the control signal generator generates a frequency band signal denoting information operable to switch between a plurality of frequency bands; and
the current signal generator controls the amplitude of the current signal based on the frequency band signal.

13. The oscillator described in claim 11, wherein:
the control signal generator generates a capacitance control signal denoting the voltage at both ends of the variable capacitance device; and
the current signal generator controls the amplitude of the current signal based on the capacitance control signal.

14. The oscillator described in claim 11, wherein:
the control signal generator generates a temperature characteristic signal denoting change in capacitance due to temperature based on at least one of the variable capacitance device and the fixed capacitor; and
the current signal generator controls the amplitude of the current signal based on the temperature characteristic signal.

15. The oscillator described in claim 14, further comprising:
a temperature sensor operable to measure the temperature of at least one of the variable capacitance device and the fixed capacitor; and
a storage circuit operable to store the temperature characteristic signal;
wherein the storage circuit generates the temperature characteristic signal based on the temperature measured by the temperature sensor.

16. The oscillator described in claim 15, wherein the temperature characteristic signal denotes the change in capacitance due to temperature and the capacitance control signal.
